(19) United States
(12) Patent Application Publication
(10) Pub. No.: US 2025/0143024 A1
(43) Pub. Date: May 1, 2025

(54) III-NITRIDE SEMICONDUCTOR LIGHT EMITTING DEVICE AND METHOD OF EMITTING RED LIGHT USING THE SAME

(71) Applicant: Soft-Epi Inc., Gyeonggi-do (KR)

(72) Inventors: Sung Min HWANG, Gyeonggi-do (KR); Sang Jeong AN, Gyeonggi-do (KR)

(21) Appl. No.: 18/742,146

(22) Filed: Jun. 13, 2024

(30) Foreign Application Priority Data
Oct. 31, 2023 (KR) 10-2023-0147470

(51) Int. Cl. H01L 33/32; H01L 33/00; H01L 33/04; H01L 33/22

(52) U.S. Cl. CPC H10H 20/825; H10H 20/0137; H10H 20/811; H10H 20/82

(57) ABSTRACT

The disclosure relates to a III-nitride semiconductor light emitting device comprising: a first semiconductor region having a first conductivity; a second semiconductor region having a second conductivity different from the first conductivity; and an active region which is interposed between the first semiconductor region and the second semiconductor region, has an InₓGa₁₋ₓN (0.1≤x≤0.2) region that generates light, and emits red light with an emission peak wavelength of 600 nm or more, and a method for emitting red light using the device.

### FIELD OF THE INVENTION

The disclosure generally relates to a III-nitride semiconductor light emitting device and a method for emitting red light using the same. In particular, it relates to a III-nitride semiconductor light emitting device that emits red light and a method for emitting red light using the same. Here, the III-nitride semiconductor is composed of a compound of Al(x)Ga(y)In(1-x-y)N (0≤x≤1, 0≤y≤1, 0≤x+y≤1.

### BACKGROUND OF THE INVENTION

This section provides background information related to the disclosure which is not necessarily up to date, commercially available semiconductor light emitting devices (e.g., LEDs, LDs) that emit light in the red color range are made of AlGaInP-based compound semiconductors, but recently those emitting light in yellow, amber, orange, red, and infrared ranges have been spotlighted.

FIG. 1 shows an example of a conventional III-nitride semiconductor light emitting device that emits light in a red color range. The semiconductor light emitting device includes a growth substrate 10 (e.g., a patterned C-plane sapphire substrate (PSS)), a buffer region 20 (e.g., un-doped GaN (2 μm) formed on a seed layer (GaN grown at a low temperature), an n-side contact region 30 (e.g., Si-doped GaN (2-8 μm) and Si-doped Al_{0.03}Ga_{0.97}N (1 μm)), a superlattice region 31 (e.g., 15 cycle GaN (6 nm)/In_{0.08}Ga_{0.92}N (2 nm)), 15 nm-thick Si-doped GaN 32, an In-deplete quantum well structure 41 (e.g., a quantum well made of In_{0.2}Ga_{0.8}N (2 nm) and a barrier made of GaN (2 nm)/Al_{0.13}Ga_{0.87}N (18 nm)/GaN (3 nm)), a red light emitting active region 42 (e.g., a quantum well made of InGaN (2.5 nm)-a barrier made of AlN (1.2 nm)/GaN (2 nm)/Al_{0.13}Ga_{0.87}N (18 nm)/GaN (3 nm))-a quantum well made of InGaN (2.5 nm)-a barrier made of AlN (1.2 nm)/GaN (23 nm)), a 15 nm thick GaN layer 43, a p-side region 50 (e.g., Mg-doped GaN (100 nm) and p±GaN:Mg (10 nm)), a current spreading electrode 60 (e.g., ITO), a first electrode 70 (e.g., Cr/Ni/Au), and a second electrode 80 (e.g., Cr/Ni/Au) (Article titled “633-nm InGaN-based red LEDs grown on thick underlying GaN layers with reduced in-plane residual stress”, Applied Physics Letters, April 2020).

U.S. Pat. No. 10,396,240 also discloses a semiconductor light emitting device that emits light in a red range using an InGaN active region.

Additionally, the applicant's inventions disclosed in International Patent Publications WO/2022/240202 and WO/2023/003446, and Korean Patent Publications No. 10-2022-0153340, No. 10-2022-0164267, and No. 10-2022-0164268 can be cited as background technology.

Furthermore, the applicant's inventions utilizing M-plane growth substrates, disclosed in WO/2014/168437, WO/2014/168436, WO/2014/084667, WO/2014/168435, Chinese Patent Publication CN10-4838473B, and US Patent Publication US2016-0013275 can also be cited as background technology.

### SUMMARY OF THE INVENTION

This section provides a general summary of the disclosure and is not a comprehensive disclosure of its full scope or all of its features.

One aspect of the disclosure provides a III-nitride semiconductor light emitting device comprising: a first semiconductor region having a first conductivity; a second semiconductor region having a second conductivity different from the first conductivity; and an active region which is interposed between the first semiconductor region and the second semiconductor region, has an InₓGa₁₋ₓN (0.1≤x≤0.2) region that generates light, and emits red light with an emission peak wavelength of 600 nm or more.

According to another aspect of the disclosure, there is provided a III-nitride semiconductor light emitting device comprising: an active region that emits red light; a semi-polar plane for growing the active region that is disposed below the active region; and an m-plane growth substrate on which the active region and the semi-polar surface are grown.

According to another aspect of the disclosure, there is provided a III-nitride semiconductor light emitting device comprising: a first semiconductor region having a first conductivity; a second semiconductor region having a second conductivity different from the first conductivity; and an active region which is interposed between the first semiconductor region and the second semiconductor region and emits red light through tunneling injection.

According to another aspect of the disclosure, there is provided a III-nitride semiconductor light emitting device comprising: a first semiconductor region having a first conductivity; a second semiconductor region having a second conductivity different from the first conductivity; an active region which is interposed between the first semiconductor region and the second semiconductor region, has an InₓGa₁₋ₓN (0.1≤x≤0.2) region that generates light, and emits red light with an emission peak wavelength of 600 nm or more; a III-nitride semiconductor layer having a cavity under the first semiconductor region; and a growth substrate under the III-nitride semiconductor layer.

According to another aspect of the disclosure, there is provided a method for emitting red light using a III-nitride semiconductor light emitting device, the method comprising: manufacturing a III-nitride semiconductor light emitting device comprising: a first semiconductor region having a first conductivity; a second semiconductor region having a second conductivity different from the first conductivity; an active region which is interposed between the first semiconductor region and the second semiconductor region, has an InₓGa₁₋ₓN (0.1≤x≤0.2) region that generates light, and emits red light with an emission peak wavelength of 600 nm or more; a III-nitride semiconductor layer having a cavity under the first semiconductor region; and an m-plane growth substrate under the III-nitride semiconductor layer; and emitting red light from the active region by passing current through the first and second semiconductor regions.

According to another aspect of the disclosure, there is provided a method for emitting red light using a III-nitride semiconductor light emitting device, the method comprising: manufacturing a III-nitride semiconductor light emitting device comprising: a first semiconductor region having a first conductivity; a second semiconductor region having a second conductivity different from the first conductivity; and an active region which is interposed between the first semiconductor region and the second semiconductor region, has an InₓGa₁₋ₓN (0.1≤x≤0.2) region that generates light, and emits red light with an emission peak wavelength of 600 nm or more; and emitting red light from the active region by passing current through the first and second semiconductor regions.

A person of ordinary skill in the art will understand, that any method described above or below and/or claimed and described as a sequence of steps is not restrictive in the sense of the order of steps.

### BRIEF DESCRIPTION OF THE DRAWINGS

Various objects, features and attendant advantages of the present invention will become fully appreciated when considered in conjunction with the accompanying drawings, in which like reference characters designate the same or similar parts throughout the several views, and wherein:

FIG. 1 shows an example of a conventional III-nitride semiconductor light emitting device that emits light in a red range;

FIG. 2 shows an example of a III-nitride semiconductor light emitting device according to the disclosure;

FIG. 3 shows examples of a semiconductor light emitting structure according to the disclosure;

FIG. 4 shows other examples of a semiconductor light emitting structure according to the disclosure;

FIG. 5 shows another example of a semiconductor light emitting structure according to the disclosure;

FIG. 6 shows an example of experiment results in the disclosure;

FIG. 7 shows another example of experiment results in the disclosure;

FIG. 8 shows another example of experiment results in the disclosure;

FIG. 9 shows another example of experiment results in the disclosure;

FIG. 10 shows another example of experiment results in the disclosure;

FIG. 11 illustrates bandgap energy of different semiconductor light emitting devices according to the disclosure;

FIGS. 12, 13 and 14 show further examples of experiment results in the disclosure;

FIG. 15 compares an active region of the quantum well structure with an active region of the superlattice structure;

FIG. 16 shows an example of experiment results of the semiconductor light emitting structure described in Table 7;

FIG. 17 illustrates various examples of semiconductor light emitting structures employing a superlattice structure;

FIG. 18 shows another example of a semiconductor light emitting structure according to the disclosure;

FIGS. 19, 20 and 21 illustrate a superlattice region and a lateral enhancement layer;

FIG. 22 shows another example of a semiconductor light emitting structure according to the disclosure;

FIGS. 23, 24, 25 and 26 show experiment results of the examples shown in FIGS. 18 to 22;

FIG. 27 shows an example of photoluminescence (PL) experiment results in the disclosure;

FIG. 28 shows an example of field luminescence (EL) experiment results in the disclosure;

FIG. 29 shows an example of field luminescence (EL) experiment results with a laser being added according to the disclosure;

FIGS. 30 to 32 illustrate the luminescence principle according to the disclosure;

FIGS. 33, 34 and 35 show other examples of measurement results in the disclosure;

FIG. 36 shows another example of a semiconductor luminescence structure or light emitting device according to the disclosure;

FIG. 37 shows an example of a III-nitride semiconductor stack according to the disclosure;

FIG. 38 shows an example of a method for growing a III-nitride semiconductor on a seed layer according to the disclosure;

FIG. 39 shows another example of a method for growing a III-nitride semiconductor on a seed layer according to the disclosure;

FIG. 40 shows another example of a III-nitride semiconductor stack according to the disclosure;

FIG. 41 shows another example of III-nitride semiconductor stack according to the disclosure;

FIG. 42 shows another example of a III-nitride semiconductor stack according to the disclosure,

FIG. 43 shows sectional images of the III-nitride semiconductor stack of FIG. 37 grown with the structure of FIG. 39;

FIG. 44 shows sectional images of the III-nitride semiconductor stack of FIG. 37 grown with the structure of FIG. 39;

FIG. 45 is a photograph showing a seed layer grown at a low temperature and a seed layer grown in a hydrogen atmosphere;

FIG. 46 is a photograph showing a seed layer grown according to the disclosure;

FIGS. 47 to 48 show an example of a method for growing a III-nitride semiconductor according to the disclosure.

### DETAILED DESCRIPTION OF THE PREFERRED EMBODIMENTS

The disclosure will now be described in detail with reference to the accompanying drawing(s).

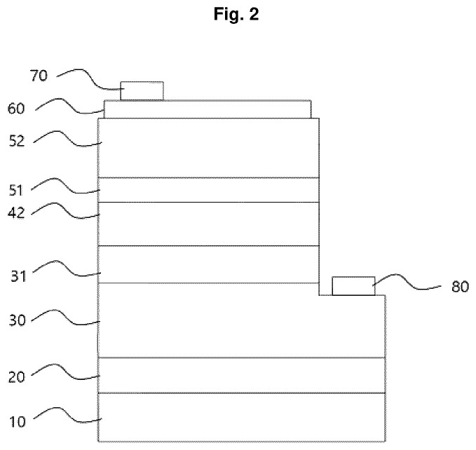

FIG. 2 shows an example of a III-nitride semiconductor light emitting device according to the disclosure, in which the semiconductor light emitting device includes a growth substrate 10, a buffer region 20, an n-side contact region 30, a superlattice region 31. a semiconductor light emitting structure or active region 42, an electron blocking layer 51 (EBL), a p-side contact region 52, a current spreading electrode 60, a first electrode 70, and a second electrode 80.

The growth substrate 10 may be a sapphire substrate, a Si 111 substrate or the like. In particular, a patterned C-face sapphire substrate (C-face PSS) may be used, and there is no particular limitation on the use of heterogeneous or homogeneous substrates.

The buffer region 20 may be made of un-doped GaN that is formed on the seed layer, and its growth conditions (based on MOVCD method) are as follows: a temperature of 950° C. to 1100° C., a thickness of 1 to 4 μm, a pressure of 100 to 400 mbar, and H₂ atmosphere.

The n-side contact region 30 may be made of Si-doped GaN, and its growth conditions are as follows: a temperature of 1000° C. to 1100° C., a thickness of 1 to 4 μm, a pressure of 100 to 400 mbar, and H₂ atmosphere.

The superlattice region 31 is a stack of InₐGa₁₋ₐN/In_{b}Ga_{1-b}N (15 cycles of repetition of 0<a<1, 0≤b<1, a>b) superlattice structure that is formed under general growth conditions to improve current spreading. Optionally, Al can be added, and it can be doped with an n-type dopant (e.g., Si). Further, the composition may be slightly changed during the repetition process.

The electron blocking layer 51 may be made of Mg-doped AlGaN, and its growth conditions are as follows: a temperature of 900° C., a thickness of 10 to 40 nm, a pressure of 50 to 100 mbar, and H₂ atmosphere.

The p-side contact region 52 can also be made of Mg-doped GaN under normal growth conditions.

The current spreading electrode 60 may be made of TCO (Transparent Conductive Oxide) such as ITO, but it is not limited thereto.

The first electrode 70 and the second electrode 80 may be made of Cr/Ni/Au.

The structure used in the example of FIG. 2 is a very common structure conventionally used to make semiconductor light emitting devices that emit blue and green light using III-nitride semiconductors. Any structure suitable for III-nitride semiconductor light emitting devices that emit blue and green light can be used without any specific limitations. While a lateral chip is illustrated in this example, any other form such as a flip chip and vertical chip may also be used. For example, the light emitting device shown here has a chip form, but it can obviously have a wafer state as well.

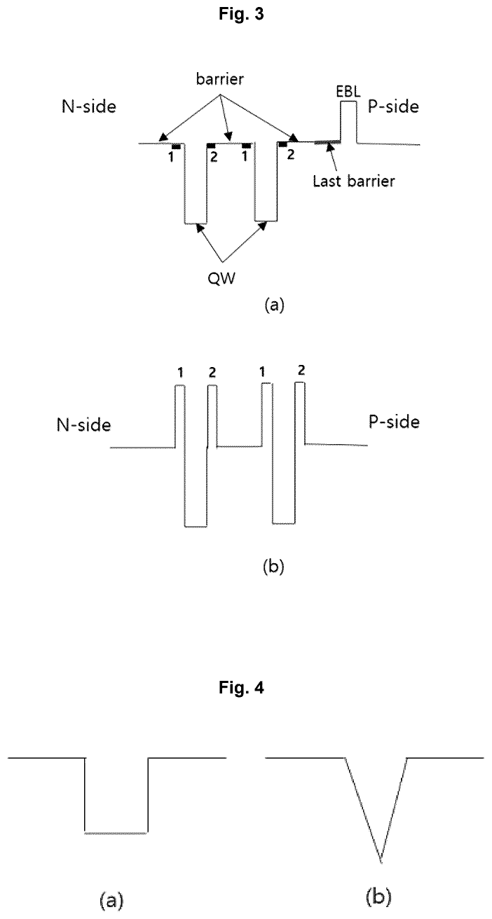

FIG. 3 shows examples of a semiconductor light emitting structure according to the disclosure. FIG. 3A shows a conventional III-nitride semiconductor light emitting structure that emits light in a green range, and FIG. 3B shows a III-nitride semiconductor light emitting structure according to the disclosure. For illustration purposes, two quantum wells are presented.

The semiconductor light emitting structure shown in FIG. 3A employs a quantum well (QW) made of In_{c}Ga_{1-c}N and a barrier made of Al_{d}GaₑIn_{1-d-e}N (0≤d≤1, 0≤e≤1; e.g., GaN). The content c of In significantly varies depending on the peak wavelength at which the semiconductor light emitting structure emits light. For example, in case of blue light emission, c can have a value of 0.1; in case of green light emission, c can have a value of 0.2. Examples of the barrier may include InGaN, AlGaN, AlGaInN, and the like, but GaN is typically used.

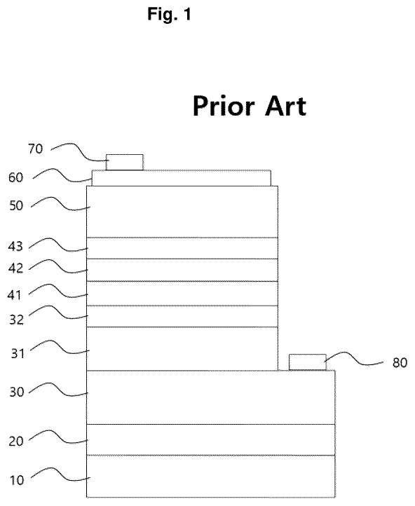

The semiconductor light emitting structure according to the disclosure is a combination of the semiconductor light emitting structure as shown in FIG. 3A, which has already been commercially available and stably implemented, with the barrier structure as shown in FIG. 3B, such that light of longer wavelengths can be emitted. Incorporating the semiconductor light emitting structure of the disclosure enables to overcome the issues in the In-rich InGaN active region of FIG. 1, as well as the issues in the operation of the semiconductor light emitting device thus manufactured.

TABLE 1

| | First (x), | First (x), | First (o), | First (o), |
|---|---|---|---|---|
| | Second (x) | Second (o) | Second (x) | Second (o) |
| Wavelength | 530 | 560 | 580 | 625 |
| (Wp, nm) | (Green) | | | (Red) |
| Optical power | Bright | Dim | Moderate | Moderate |
| (Qualitative | | | | |
| evaluation) | | | | |

As described in Table 1, (i) when neither the first layer 1 nor the second layer 2 according to the disclosure is not provided on either side of the quantum well, the device emits bright light with a wavelength Qh of 530 nm, (ii) when only the second layer 2 according to the disclosure is provided in the quantum well, the device emits dim light with a wavelength of 560 nm, (iii) when only the first layer 1 according to the disclosure is provided in the quantum well, the device emits light of moderate brightness with a wavelength of 580 nm, and (iv) when both the first layer 1 and the second layer 2 according to the disclosure are provided on both sides of the quantum well, the device emits light of moderate brightness with a wavelength of 625 nm.

FIG. 4 shows other examples of a semiconductor light emitting structure according to the disclosure. FIG. 4A shows an example in which In is uniformly distributed during the formation of a quantum well. FIG. 4B shows an example in which the distribution of In is graded (that is, it is first decreased and then increased) during the formation of the quantum well. When the same total amount of In was provided to each quantum well, the structure in FIG. 4B exhibited brighter light.

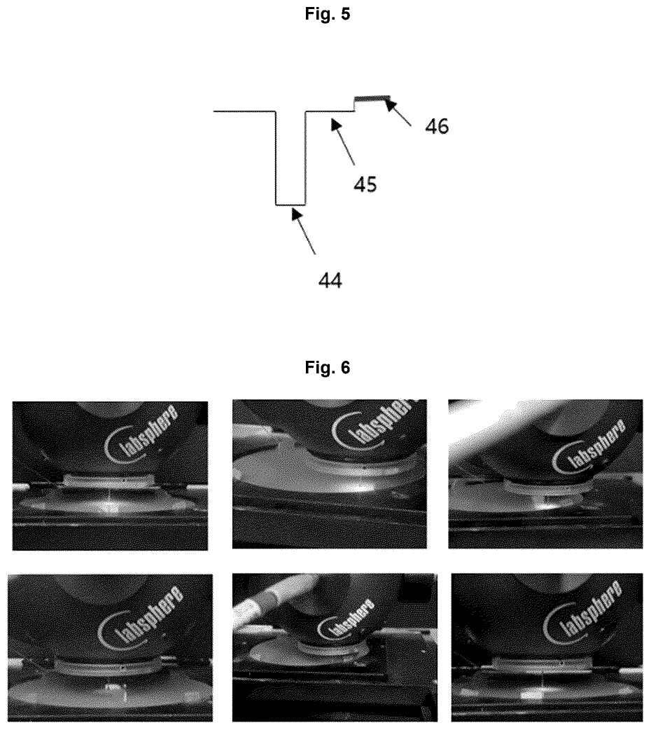

FIG. 5 shows another example of a semiconductor light emitting structure according to the disclosure. It demonstrates that changing the material composition of the last barrier (the barrier closest to the p-side in the semiconductor light emitting structure) from GaN to another material (such as InGaN) having a lower bandgap energy than GaN can extend the emission wavelength of the semiconductor light emitting structure. For example, it was confirmed that if an In/(In+Ga) ratio is appropriately adjusted (e.g., 0.05 or 0.10; where the ratio indicates the molar ratio between MO sources (TEGa (TriEthyl Ga), TMIn (TriMethyl In), TMAI (TriMethyl Al) in the vapor phase during growth), a semiconductor light emitting structure that emits light with a wavelength of 625 nm is capable of emitting light with a wavelength of 635 nm.

FIG. 6 shows an example of experiment results in the disclosure. The top left illustrates a case where both the first layer 1 and the second layer 2 are absent (green); the top middle illustrates a case where only the second layer 2 is present (yellow); the top right illustrates a case where only the first layer 1 is present (orange); the bottom left illustrates a case where both the first layer 1 and the second layer 2 are present (red); the bottom middle illustrates a case in FIG. 5 (redder or more intense red); and the bottom right illustrates a case where Al_{f}Ga_{1-f}N (the ratio of Al/(Al+Ga) is 0.95) is used (blue).

For the experiments, a GaN barrier (4 nm) and an In_{c}Ga_{1-c}N well layer (2.5 nm) with an In/(In+Ga) ratio of 0.56 were used. In particular, two quantum wells were used to form a base structure as follows: GaN barrier (4 nm)-In_{c}Ga_{1-c}N well layer (2.5 nm)-GaN barrier (4 nm)-In_{c}Ga_{1-c}N well layer (2.5 nm)-GaN barrier (8 nm). Although 1 to 4 quantum wells were tested due to limitations in the experiments, there were no significant variations in the optical properties. For the first layer 1 and the second layer 2, Al_{f}Ga_{1-f}N (2 nm) with an Al/(Al+Ga) ratio of 0.85 was used.

The well layers (quantum wells) were grown to a thickness of 2.5 nm at a temperature of 670° C. using TMGa and TMIn, and the barriers were grown to a thickness of 4 nm at a temperature of 770° C. using GaN. For the first layer 1 located first on the n-side, Al_{f}Ga_{1-f}N (2 nm) with an Al/(Al+Ga) ratio of 0.85 is grown using TMAI and TMGa under the same conditions as the first barrier immediately after the growth of the first barrier (located first on the n-side) (they together form the barrier). Once the first quantum well (the first well layer located on the n-side) is grown, the second layer 2 located on the n-side is grown to a thickness of 0.3 nm using TMGa and TMAI by raising the temperature for 50 seconds. Afterwards, the remaining 1.7 nm is grown under the same growth conditions as the barrier, and the GaN barrier is grown. The first layer 1 and the second layer 2 located on the p-side are also grown in the same manner. The semiconductor light emitting structure 42 provided with the first layer 1 as well as the second layer 2 has the structure of the last GaN (1.5 nm) in the superlattice region 31-GaN barrier (4 nm)-first Al_{f}Ga_{1-f}N (2 nm) layer 1-In_{c}Ga_{1-c}N well layer (2.5 nm)-second Al_{f}Ga_{1-f}N (2 nm) layer 2-GaN barrier (4 nm)-first Al_{f}Ga_{1-f}N (2 nm) layer 1-In_{c}Ga_{1-c}N well layer (2.5 nm)-second Al_{f}Ga_{1-f}N (2 nm) layer 2-GaN barrier (8 nm)-electron blocking layer 51. In the semiconductor light emitting structure shown in FIG. 5, the last barrier (adjacent to the electron blocking layer 51) can have the structure of In_{g}Ga_{1-g}N barrier (4 nm)-GaN barrier (4 nm).

As shown in FIG. 6, the emission wavelength can be shifted to a longer range by introducing the first layer 1 and/or the second layer 2 into a given semiconductor light emitting structure. However, as shown in the bottom right of FIG. 6, it is observed when the Al concentration in the first and second layers 1 and 2 is beyond a certain threshold, the wavelength shifts toward a shorter range compared to the original emission wavelength of the semiconductor light emitting structure.

Table 2 below summarizes examples of growth conditions for conventional superlattice regions 31. As described earlier, the composition in the disclosure is represented by the molar ratio between MO sources (TriEthyl Ga (TEGa), TriMethyl In (TMIn), and TriMethyl Al (TMAl).

TABLE 2

| | Growth | | |
|---|---|---|---|
| | temperature | Composition | Thickness |
| InₐGa₁₋ₐN | 720° C. | In/(In + Ga) = | 1.5 nm |
| (Superlattice region (31)) | | 0.55 | |
| In_{b}Ga_{1-b} N | 780° C. | b = 0 (GaN) | 1.5 nm |
| (Superlattice region (31)) | | | |

Here, the superlattice region 31 may be fully or partially doped. For example, only the barrier In_{b}Ga_{1-b}N (superlattice region 31) may be doped with Si at about 5×10¹⁸/cm³, or only the even-numbered barriers may be doped, or only the odd-numbered barriers may be doped.

Table 3 below summarizes examples of growth conditions for the conventional semiconductor light emitting structure or active region 42.

TABLE 3

| | Growth | | | |
|---|---|---|---|---|
| | temperature | Composition | Thickness | |
| AlₐGaₑIn_{1-d-e}N barrier | 770° C. | d = 0, e = 1 | 4 | nm |
| (Semiconductor light emitting | | (GaN) | | |
| structure (42)) | | | | |
| In_{c}Ga_{1-c}N well layer | 670° C. | In/(In + Ga) = | 2.5 | nm |
| (Semiconductor light emitting | | 0.56 | | |
| structure (42)) | | | | |
| AlₐGaₑIn_{1-d-e}N barrier | 770° C. | d = 0, e = 1 | 4 | nm |
| (Semiconductor light emitting | | (GaN) | | |
| structure (42)) | | | | |
| In_{c}Ga_{1-c}N well layer | 670° C. | In/(In + Ga) = | 2.5 | nm |
| (Semiconductor light emitting | | 0.56 | | |
| structure (42)) | | | | |
| AlₐGaₑIn_{1-d-e}N barrier | 770° C. | d = 0, e = 1 | 8 | nm |
| (Semiconductor light emitting | | (GaN) | | |
| structure (42)) | | | | |

Table 4 below summarizes examples of growth conditions used for the semiconductor light emitting structure or active region 42 according to the disclosure.

TABLE 4

| | Growth | | | |
|---|---|---|---|---|
| | temperature | Composition | Thickness | |
| Al_{d}GaₑIn_{1-d-e}N barrier | 770° C. | d = 0, e = 1 | 4 | nm |
| (Semiconductor light emitting | | (GaN) | | |
| structure (42)) | | | | |
| First Al_{f}Ga_{1-f}N layer (1) | 770° C. | Al/(Al + Ga) = | 2 | nm |
| | | 0.85 | | |
| In_{c}Ga_{1-c}N well layer | 670° C. | In/(In + Ga) = | 2.5 | nm |
| (Semiconductor light emitting | | 0.56 | | |
| structure (42)) | | | | |
| Second Al_{f}Ga_{1-f}N layer (2) | 770° C. | Al/(Al + Ga) = | 2 | nm |
| | | 0.85 | | |
| Al_{d}GaₑIn_{1-d-e}N barrier | 770° C. | d = 0, e = 1 | 4 | nm |
| (Semiconductor light emitting | | (GaN) | | |
| structure (42)) | | | | |
| First Al_{f}Ga_{1-f}N layer (1) | 770° C. | Al/(Al + Ga) = | 2 | nm |
| | | 0.85 | | |
| In_{c}Ga_{1-c}N well layer | 670° C. | In/(In + Ga) = | 2.5 | nm |
| (Semiconductor light emitting | | 0.56 | | |
| structure (42)) | | | | |
| Second Al_{f}Ga_{1-f}N layer (2) | 770° C. | Al/(Al + Ga) = | 2 | nm |
| | | 0.85 | | |
| Al_{d}GaₑIn_{1-d-e}N barrier | 770° C. | d = 0, e = 1 | 8 | nm |
| (Semiconductor light emitting | | (GaN) | | |
| structure (42)) | | | | |

Table 5 below summarizes examples of growth conditions used for the semiconductor light emitting structure or active region 42, as shown in FIG. 5.

TABLE 5

| | Growth | | | |
|---|---|---|---|---|
| | temperature | Composition | Thickness | |
| Al_{d}GaₑIn_{1-d-e}N barrier | 770° C. | d = 0, e = 1 | 4 | nm |
| (Semiconductor light | | (GaN) | | |
| emitting structure (42)) | | | | |
| First Al_{f}Ga_{1-f}N | 770° C. | Al/(Al + Ga) = | 2 | nm |
| layer (1) | | 0.85 | | |
| In_{c}Ga_{1-c}N well layer | 670° C. | In/(In + Ga) = | 2.5 | nm |
| (Semiconductor light | | 0.56 | | |
| emitting structure (42)) | | | | |
| Second Al_{f}Ga_{1-f}N | 770° C. | Al/(Al + Ga) = | 2 | nm |
| layer (2) | | 0.85 | | |
| Al_{d}GaₑIn_{1-d-e}N barrier | 770° C. | d = 0, e = 1 | 4 | nm |
| (Semiconductor light | | (GaN) | | |
| emitting structure (42)) | | | | |
| First Al_{f}Ga_{1-f}N | 770° C. | Al/(Al + Ga) = | 2 | nm |
| layer (1) | | 0.85 | | |
| In_{c}Ga_{1-c}N well layer | 670° C. | In/(In + Ga) = | 2.5 | nm |
| (Semiconductor light | | 0.56 | | |
| emitting structure (42)) | | | | |
| Second Al_{f}Ga_{1-f}N | 770° C. | Al/(Al + Ga) = | 2 | nm |
| layer (2) | | 0.85 | | |
| In_{g}Ga_{1-g}N well layer | 770° C. | In/(In + Ga) = | 4 | nm |
| (Semiconductor light | | 0.01 | | |
| emitting structure (42)) | | | | |
| Al_{d}GaₑIn_{1-d-e}N barrier | 770° C. | d = 0, e = 1 | 4 | nm |
| (Semiconductor light | | (GaN) | | |
| emitting structure (42)) | | | | |

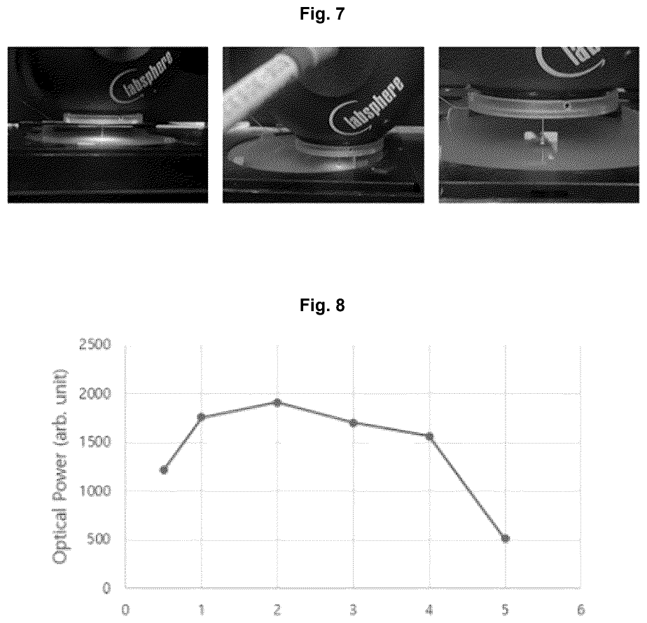

FIG. 7 shows another example of experiment results in the disclosure, related to changes in the emission wavelength based on the Al content in the semiconductor light emitting structure. The left illustrates a case where if the ratio of Al/(Al+Ga) is 0.25, yellow emission occurs; the middle illustrates a case where if the ratio of Al/(Al+Ga) is 0.75, red emission occurs; and the right illustrates a case where if the ratio of Al/(Al+Ga) is 0.95, blue emission occurs. With the semiconductor light emitting structure used in the experiment of FIG. 6, a significant change in the wavelength occurs when the Al content exceeds 20%, but the wavelength gets shorter again when the Al content exceeds 90%.

FIG. 8 shows another example of experiment results in the disclosure, related to variations in optical power based on a change in the thickness of the first layer 1 and the second layer 2. With the semiconductor light emitting structure shown in FIG. 6, the maximum intensity is observed at approximately 2 nm, but it sharply drops as the thickness reaches 5 nm. A desirable range for the thickness is therefore 0.5-4 nm.

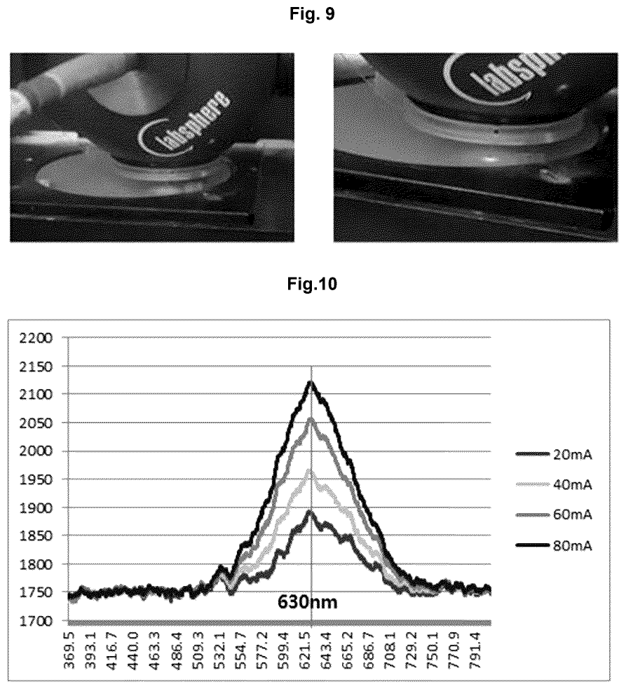

FIG. 9 shows another example of experiment results in the disclosure, comparing the results of using the semiconductor light emitting structure in FIG. 4A (on the left) with the results of using the semiconductor light emitting structure in FIG. 4B (on the right). As can be seen, the example on the right shows brighter and more intense red emission.

FIG. 10 shows another example of experiment results in the disclosure, related to the degree of wavelength shift with changes in current. As compared with the conventional In-rich InGaN red LED (which shows a drastic shift towards shorter wavelengths with increased current), the wavelength shift is much less pronounced in this example.

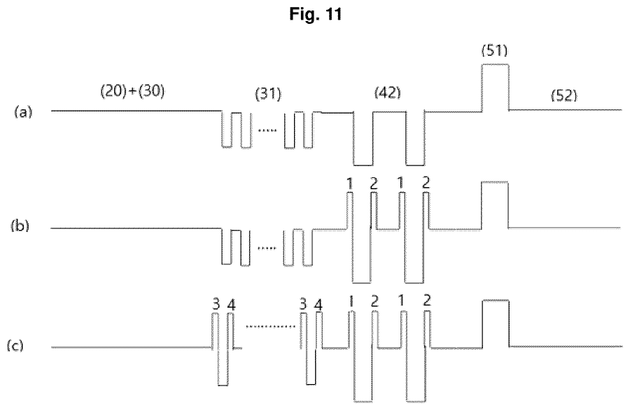

FIG. 11 illustrates bandgap energy of different semiconductor light emitting devices. FIG. 11A is obtained from a conventional semiconductor light emitting device, FIG. 11B is obtained from the semiconductor light emitting device shown in FIG. 2, and FIG. 11C is obtained from a semiconductor light emitting device which incorporates the barrier form of the semiconductor light emitting structure 42 into the superlattice region 31 in the structure shown in FIG. 11B.

Table 6 below summarizes examples of growth conditions used for the semiconductor light emitting device shown in FIG. 11C.

TABLE 6

| | Growth | | | |
|---|---|---|---|---|
| | temperature | Composition | Thickness | |
| Third Al_{g}Ga_{1-g}N | 780° C. | Al/(Al + Ga) = | 0.8 | nm |
| layer (3) | | 0.50 | | |
| InₐGa₁₋ₐN well layer | 720° C. | In/(In + Ga) = | 1.5 | nm |
| (Superlattice region (31)) | | 0.55 | | |
| Fourth Al_{g}Ga_{1-g}N | 780° C. | Al/(Al + Ga) = | 0.8 | nm |
| layer (4) | | 0.50 | | |
| In_{b}Ga_{1-b}N well layer | 780° C. | b = 0 | 1.5 | nm |
| (Superlattice region (31)) | | (GaN) | | |
| . | . | . | . | |
| . | . | . | . | |
| . | . | . | . | |
| <<15 cycles>> | | | | |
| . | . | . | . | |
| . | . | . | . | |
| . | . | . | . | |
| Third Al_{g}Ga_{1-g}N | 780° C. | Al/(Al + Ga) = | 0.8 | nm |
| layer (3) | | 0.50 | | |
| InₐGa₁₋ₐN well layer | 720° C. | In/(In + Ga) = | 1.5 | nm |
| (Superlattice region (31)) | | 0.55 | | |
| Fourth Al_{g}Ga_{1-g}N | 780° C. | Al/(Al + Ga) = | 0.8 | nm |
| layer (4) | | 0.50 | | |
| In_{b}Ga_{1-b}N well layer | 780° C. | b = 0 | 1.5 | nm |
| (Superlattice region (31)) | | (GaN) | | |
| Al_{d}GaₑIn_{1-d-e}N barrier | 770° C. | d = 0, e = 1 | 4 | nm |
| (Semiconductor light | | (GaN) | | |
| emitting structure (42)) | | | | |
| First Al_{f}Ga_{1-f}N | 770° C. | Al/(Al + Ga) = | 2 | nm |
| layer (1) | | 0.85 | | |
| In_{c}Ga_{1-c}N well layer | 670° C. | In/(In + Ga) = | 2.5 | nm |
| (Semiconductor light | | 0.56 | | |
| emitting structure (42)) | | | | |
| Second Al_{f}Ga_{1-f}N | 770° C. | Al/(Al + Ga) = | 2 | nm |
| layer (2) | | 0.85 | | |
| Al_{d}GaₑIn_{1-d-e}N barrier | 770° C. | d = 0, e = 1 | 4 | nm |
| (Semiconductor light | | (GaN) | | |
| emitting structure (42)) | | | | |
| First Al_{f}Ga_{1-f}N | 770° C. | Al/(Al + Ga) = | 2 | nm |
| layer (1) | | 0.85 | | |
| In_{c}Ga_{1-c}N well layer | 670° C. | In/(In + Ga) = | 2.5 | nm |
| (Semiconductor light | | 0.56 | | |
| emitting structure (42)) | | | | |
| Second Al_{f}Ga_{1-f}N | 770° C. | Al/(Al + Ga) = | 2 | nm |
| layer (2) | | 0.85 | | |
| Al_{d}GaₑIn_{1-d-e}N barrier | 770° C. | d = 0, e = 1 | 8 | nm |
| (Semiconductor light | | (GaN) | | |
| emitting structure (42)) | | | | |

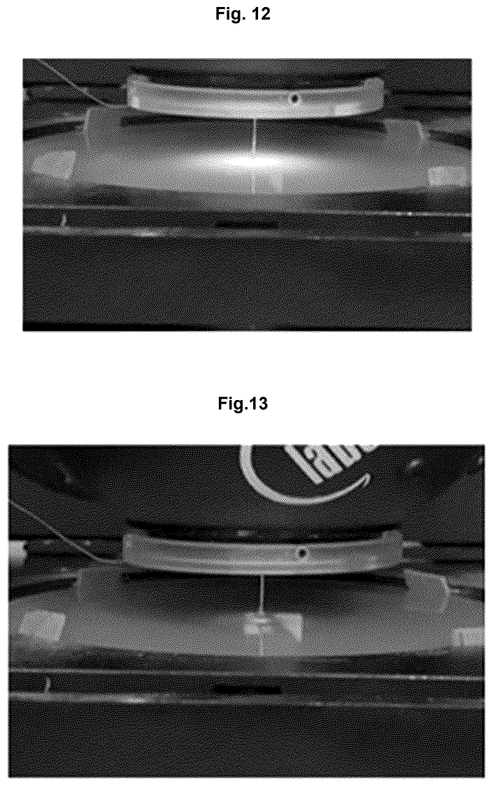

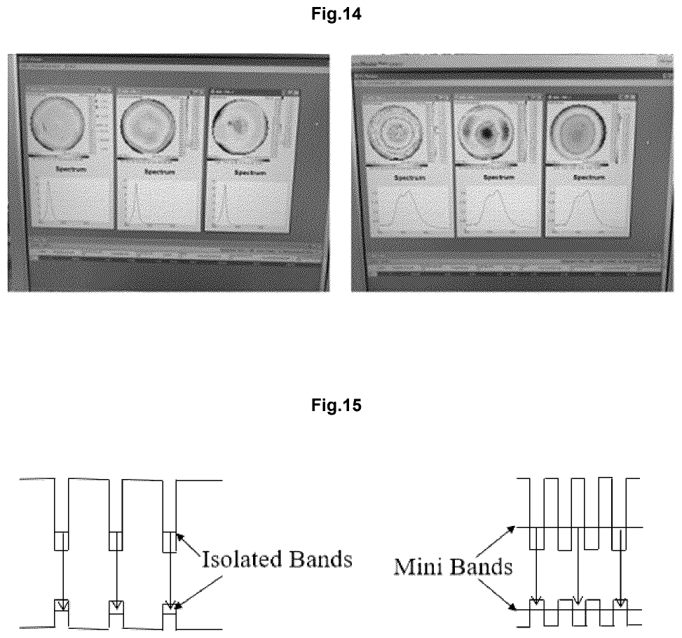

FIGS. 12 to 14 show further examples of experiment results in the disclosure. In particular, FIG. 12 shows experiment results for the semiconductor light emitting device of FIG. 11C, for which all growth conditions are kept the same as in FIG. 11B except that the quantum well region 31 is absent. Similar to the example on the right side in FIG. 7, a shift towards shorter wavelengths is observed. This suggests that the incorporation of the third and fourth layers 3 and 4, into the superlattice region 31 (i.e. the superlattice region 31 as shown in FIG. 11C) increases the amount of In injected into the well layers of the semiconductor light emitting structure 42. FIG. 13 shows that when the ratio of Al/(Al+Ga) in the first and second layers 1 and 2 is lowered from 0.85 to 0.45, red light emission (635 nm) is at least twice as that of the semiconductor light emitting device of FIG. 11B. FIG. 14 shows PL measurement results of the superlattice region 31 with or without the third and fourth layers 3 and 4. The results confirm that in the presence of the third and fourth layers 3 and 4, the PL peak makes a significant shift in longer wavelength ranges, from 445 nm to 535 nm.

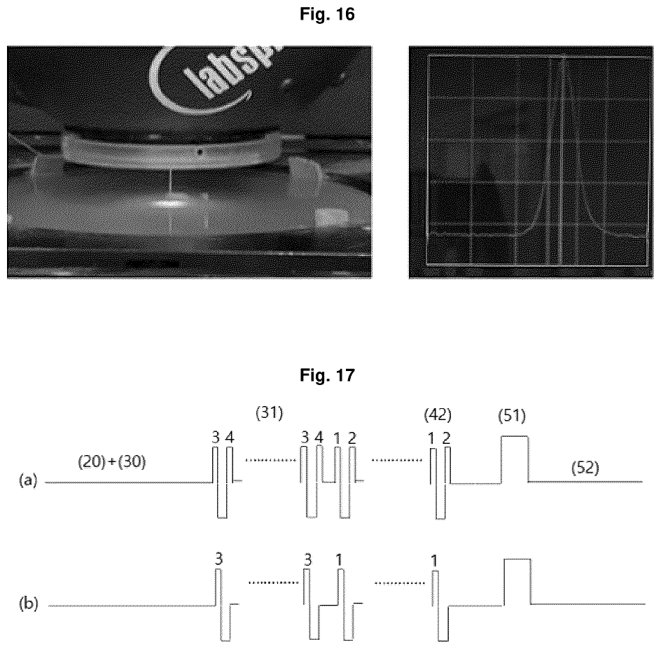

Table 7 below summarizes examples of growth conditions for the semiconductor light emitting device of FIG. 11C, in which the active region 42 of the quantum well structure is modified to a semiconductor light emitting region or active region 42 of the superlattice structure similar to the superlattice region 31. Referring to FIG. 15 which compares the active region of the quantum well structure (the left) with the active region of the superlattice structure (the right), each quantum well in the active region of the quantum well structure forms isolated bands due to a thick barrier and emits light independently through electron-hole recombination, while each well in the active region of the superlattice structure (that is, the barrier becomes sufficiently thin) is not isolated and forms minibands to emit light through miniband transition. Although the active region of the superlattice structure is not commonly used in III-nitride semiconductor light emitting devices, it was found to be very effective when applied to the semiconductor light emitting structure of the disclosure (see FIG. 16). That is to say, the active region 42 is constructed to be the same as the superlattice region 31, with some specific conditions as follows: 8 cycles are used; no doping is performed; the growth temperature for the well layers is set at 700° C., while the growth temperature for the other layers is set at 780° C., the thickness of the first and second layers 1 and 2 is set to 0.8 nm; the thickness of Al_{d}Gaₑ In_{1-d-e}N barrier (d=0, e=1 (GaN)) is set to 1.5 nm; the ratio of the well layer In/(In+Ga) is set to 0.55; the ratio of Al/(Al+Ga) in the first layer 1 and the second layer 2 is set to 0.50; and the thickness of the well layer is set to 1.5 nm.

TABLE 7

| | Growth | | | |
|---|---|---|---|---|
| | temperature | Composition | Thickness | |
| Third Al_{g}Ga_{1-g}N | 780° C. | Al/(Al + Ga) = | 0.8 | nm |
| layer (3) | | 0.50 | | |
| InₐGa₁₋ₐN well layer | 720° C. | In/(In + Ga) = | 1.5 | nm |
| (Superlattice region (31)) | | 0.55 | | |
| Fourth Al_{g}Ga_{1-g}N | 780° C. | Al/(Al + Ga) = | 0.8 | nm |
| layer (4) | | 0.50 | | |
| In_{b}Ga_{1-b}N well layer | 780° C. | b = 0 | 1.5 | nm |
| (Superlattice region (31)) | | (GaN) | | |
| . | . | . | . | |
| . | . | . | . | |
| . | . | . | . | |
| <<15 cycles>> | | | | |
| . | . | . | . | |
| . | . | . | . | |
| . | . | . | . | |
| Third Al_{g}Ga_{1-g}N | 780° C. | Al/(Al + Ga) = | 0.8 | nm |
| layer (3) | | 0.50 | | |
| InₐGa₁₋ₐN well layer | 720° C. | In/(In + Ga) = | 1.5 | nm |
| (Superlattice region (31)) | | 0.55 | | |
| Fourth Al_{g}Ga_{1-g}N | 780° C. | Al/(Al + Ga) = | 0.8 | nm |
| layer (4) | | 0.50 | | |
| In_{b}Ga_{1-b}N well layer | 780° C. | b = 0 | 1.5 | nm |
| (Superlattice region (31)) | | (GaN) | | |
| Al_{d}GaₑIn_{1-d-e}N barrier | 780° C. | d = 0, e = 1 | 4 | nm |
| (Semiconductor light | | (GaN) | | |
| emitting structure (42)) | | | | |
| First Al_{f}Ga_{1-f}N | 780° C. | Al/(Al + Ga) = | 0.8 | nm |
| layer (1) | | 0.50 | | |
| In_{c}Ga_{1-c}N well layer | 700° C. | In/(In + Ga) = | 1.5 | nm |
| (Semiconductor light | | 0.55 | | |
| emitting structure (42)) | | | | |
| Second Al_{f}Ga_{1-f}N | 780° C. | AI/(Al + Ga) = | 0.8 | nm |
| layer (2) | | 0.50 | | |
| Al_{d}GaₑIn_{1-d-e}N barrier | 780° C. | d = 0, e = 1 | 1.5 | nm |
| (Semiconductor light | | (GaN) | | |
| emitting structure (42)) | | | | |
| . | . | . | . | |
| . | . | . | . | |
| . | . | . | . | |
| <<8 cycles>> | | | | |
| . | . | . | . | |
| . | . | . | . | |
| . | . | . | . | |
| First Al_{f}Ga_{1-f}N | 780° C. | Al/(Al + Ga) = | 0.8 | nm |
| layer (1) | | 0.50 | | |
| In_{c}Ga_{1-c}N well layer | 700° C. | In/(In + Ga) = | 1.5 | nm |
| (Semiconductor light | | 0.55 | | |
| emitting structure (42)) | | | | |
| Second Al_{f}Ga_{1-f}N | 780° C. | Al/(Al + Ga) = | 0.8 | nm |
| layer (2) | | 0.50 | | |
| Al_{d}GaₑIn_{1-d-e}N barrier | 780° C. | d = 0, e = 1 | 8 | nm |
| (Semiconductor light | | (GaN) | | |
| emitting structure (42)) | | | | |

FIG. 16 shows an example of experiment results for the semiconductor light emitting structure described in Table 7. It confirms a 7-fold increase in output compared with the example described in Table 6.

FIG. 17 illustrates various examples of semiconductor light emitting structures employing a superlattice structure. In particular, FIG. 17A illustrates the bandgap energy of the semiconductor light emitting device described in Table 7, and FIG. 17B illustrates the semiconductor light emitting device from which the layers (i.e. the second layer 2 and the fourth layer 4) are removed from the p-side of the semiconductor light emitting structure 42 and the superlattice region 31. The semiconductor light emitting device illustrated in FIG. 17B demonstrated similar experiment results to those of the semiconductor light emitting device illustrated in FIG. 17A, under the same growth conditions but a modified ratio of Al/(Al+Ga) in the first layer 1 from 0.50 to 0.65.

In the semiconductor light emitting device illustrated in FIG. 17B, if the thickness of Al_{d}Gaₑ In_{1-d-e}N barrier (d=0, e=1 (GaN)) of the semiconductor light emitting structure 42 is reduced from 1.5 nm to 1 nm, an emission wavelength shifts from 630 nm to 640 nm, moving towards a longer wavelength.

In the semiconductor light emitting device illustrated in FIG. 17B, if the repetition cycle of the semiconductor light emitting structure 42 is modified from 8 cycles to 16 cycles, an emission wavelength shortens to 625 nm, while the power intensity stayed relatively similar.

In the semiconductor light emitting device illustrated in FIG. 17B, if the thickness of Al_{d}Gaₑ In_{1-d-e}N barrier (d=0, e=1 (GaN)) of the semiconductor light emitting structure 42 is reduced from 1.5 nm to 0.75 nm, the thickness of the first layer 1 is reduced from 0.8 nm to 0.4 nm, and the thickness of the well layer is reduced from 1.5 nm to 0.75 nm, the wavelength shortens from 630 nm to 600 nm and the optical power is lowered by at least 50%.

In the semiconductor light emitting device illustrated in FIG. 17B, if the thickness of Al_{d}Gaₑ In_{1-d-e}N barrier (d=0, e=1 (GaN)) of the semiconductor light emitting structure 42 is reduced from 1.5 nm to 1.0 nm, the thickness of the first layer 1 is remained at 0.8 nm, and the thickness of the well layer is increased from 1.5 nm to 2.0 nm, the wavelength significantly increases from 630 nm to 680 nm, while the optical power is lowered by at least 50%. With these conditions, raising the growth temperature to a higher level may change the emission wavelength back to 630 nm, while the optical power is increased by 20% as compared with the semiconductor light emitting device illustrated in FIG. 17B.

Various changes can be made, which may include adding dopants to each layer of the superlattice region 31 and the semiconductor light emitting structure 42, adding Al, In or Ga, or slightly modifying the composition and growth conditions during the repetition process.

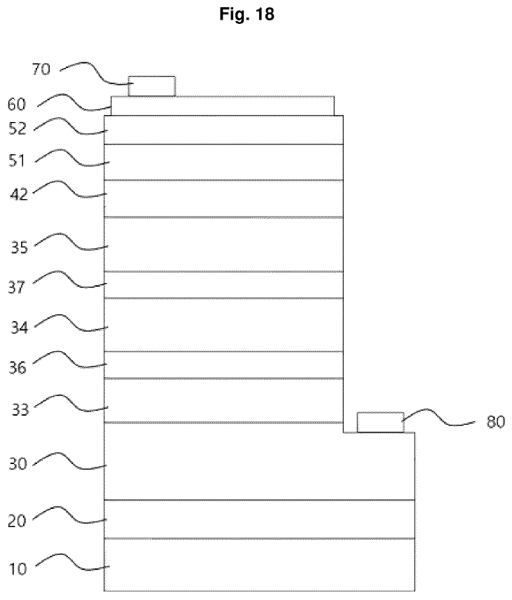

FIG. 18 shows another example of a semiconductor light emitting structure according to the disclosure. Unlike the semiconductor light emitting structure shown in FIG. 2, this example includes a plurality of superlattice regions 33, 34, 35 and uses an active region 42 with the superlattice structure is used. A lateral enhancement layer 36 is provided between the superlattice region 33 and the superlattice region 34, and a lateral enhancement layer 37 is provided between the between the superlattice region 34 and the superlattice region 35.

The superlattice regions 33, 34, 35 can be composed of sequentially repeated layers of AlGaN—InGaN—GaN, GaN—InGaN—AlGaN, GaN—AlGaN—InGaN—AlGaN, or AlGaN—InGaN. It is sufficient that the superlattice region 33, 34, 35 has therein an interface of AlGaN—InGaN, which may lead to the presence of AllnGaN either by diffusion or by intentional formation. In conventional III-nitride semiconductor light emitting devices, superlattice regions are primarily used to reduce the energy band gap difference between the n-type contact region 30 (e.g., GaN) and the active region containing InGaN. However, in this disclosure, the superlattice regions 33, 34, 35 are used not only to reduce the energy band gap as aforementioned, but also to increase the amount of In incorporated into the active region 42. Due to the large lattice constant difference between GaN and InGaN, it is difficult to incorporate In into the active region, but by increasing the In content through the superlattice regions 33, 34, 35, more In can be effectively incorporated into the active region 42. In particular, as In is introduced into the superlattice region 33, the superlattice region 34 would contain more In even under the same growth conditions, and the same applies to the superlattice region 35.

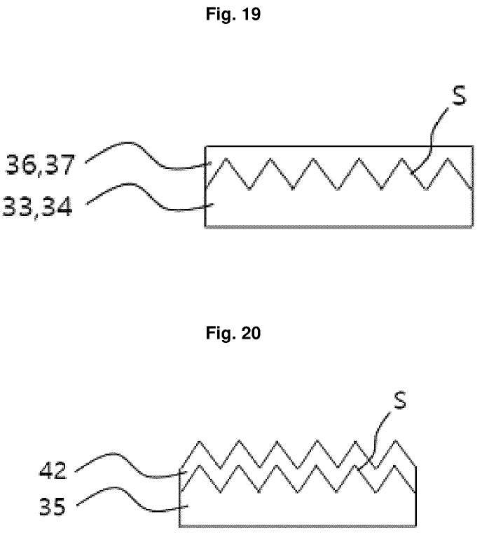

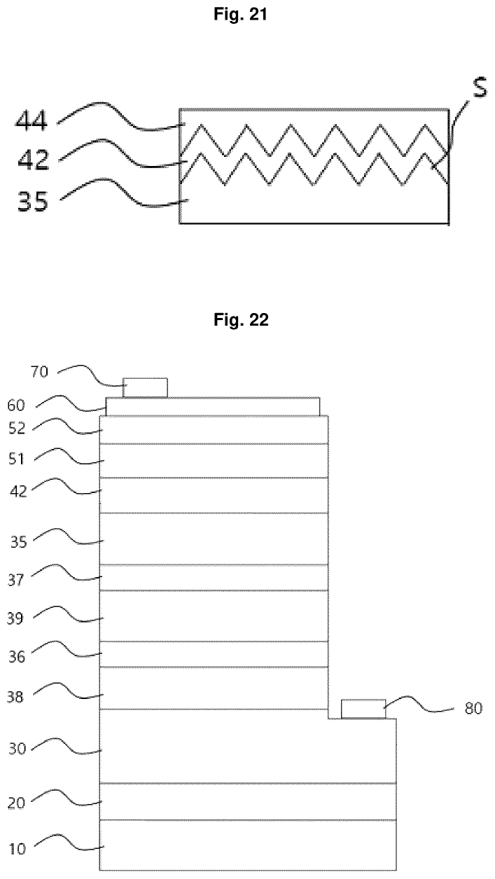

The superlattice regions 33, 34, 35 formed as described above would not have a flat surface due to the AlGaN—InGaN interface, but rather, they have a rough surface S as shown in FIGS. 19 to 21. As continuous accumulation of the rough surface S of the superlattice region 33 can increase the crystal defects of the device, a lateral enhancement layer 36 is introduced to make the surface flat, the superlattice region 34 is also introduced to facilitate the incorporation of In into the active region 42, and the lateral enhancement layer 37 is further introduced to eliminate the crystal defects. While there is no upper limit, at least one superlattice region 33, 34, 35 may be provided. More preferably, though, as shown in FIG. 21, no lateral enhancement layer is introduced between the active region 42 and the nearest superlattice region 35. The rough surface S is comprised of a semi-polar facet. For example, when the growth substrate 10 is a C-plane sapphire substrate, a flat, III-nitride semiconductor grown thereon has a polar facet which grows along the c-axis, but a three dimensional surface which forms the rough surface S comprises a semi-polar faucet. A polar facet makes In injection easier, but it has a high piezoelectric constant (that is, when the piezoelectric constant is high, the wavelength can shift significantly toward shorter wavelength ranges as the current density increases). Meanwhile, a non-polar facet has zero piezoelectric constant is 0 but it makes In injection difficult. Therefore, this disclosure has grown the active region 42 on a rough surface S which is a semi-polar facet, facilitating In injection with an appropriate piezoelectric constant. As shown in FIG. 21, it is possible to grow the last barrier 44 of the active region 42 flat or in the shape of the rough surface S, by adjusting the growth conditions.

Table 8 below summarizes examples of growth conditions for the semiconductor light emitting structure of FIG. 18.

TABLE 8

| | Growth | | |
|---|---|---|---|
| | temperature | Composition | Thickness |
| GaN | 830° C. | | 1.5 nm |
| (Superlattice region (33)) | | | |
| InₓGa₁₋ₓN | 730° C. | x = 0.1 | 1.5 nm |
| (Superlattice region (33)) | | | |
| Al_{y}Ga_{1-y}N | 780° C. | y = 0.5 | 0.5 nm |
| (Superlattice region (33)) | | | |
| . | . | . | . |
| . | . | . | . |
| . | . | . | . |
| <<10 cycles>> | | | |
| . | . | . | . |
| . | . | . | . |
| . | . | . | . |
| GaN | 830° C. | | 100 |
| (Lateral enhancement layer | | | |
| (36)) | | | |
| GaN | 830° C. | | 1.5 |
| (Superlattice region (34)) | | | |
| InₓGa₁₋ₓN | 730° C. | x = 0.1 | 1.5 |
| (Superlattice region (34)) | | | |
| Al_{y}Ga_{1-y}N | 780° C. | y = 0.5 | 0.5 |
| (Superlattice region (34)) | | | |
| . | . | . | . |
| . | . | . | . |
| . | . | . | . |
| <<10 cycles>> | | | |
| . | . | . | . |
| . | . | . | . |
| . | . | . | . |
| GaN | 830° C. | | 100 |
| (Lateral enhancement layer | | | |
| (37)) | | | |
| Al_{y}Ga_{1-y}N | 780° C. | y = 0.5 | 0.5 |
| (Superlattice region (35)) | | | |
| InₓGa₁₋ₓN | 730° C. | x = 0.1 | 1.5 |
| (Superlattice region (35)) | | | |
| GaN | 830° C. | | 1.5 |
| (Superlattice region (35)) | | | |
| . | . | . | . |
| . | . | . | . |
| . | . | . | . |
| <<10 cycles>> | | | |
| . | . | . | . |
| . | . | . | . |
| . | . | . | . |
| InₓGa₁₋ₓN | 710° C. | x = 0.35 | 2.2 |
| (Active region (42)) | | | |
| InₓGa₁₋ₓN | 760° C. | x= 0.05 | 0.4 |
| (Active region (42)) | | | |
| Al_{y}Ga_{1-y}N | 760° C. | y = 0.1 | 0.8 |
| (Active region (42)) | | | |
| InₓGa₁₋ₓN | 760° C. | x = 0.05 | 0.4 |
| (Active region (42)) | | | |
| . | . | . | . |
| . | . | . | . |
| . | . | . | . |
| <<3 cycles>> | | | |
| . | . | . | . |
| . | . | . | . |
| . | . | . | . |
| Al_{y}Ga_{1-y}N | 760° C. | y = 0.05 | 6 |
| (Last barrier (44)) | | | |
| GaN | 760° C. | | 6 |
| (Last barrier (44)) | | | |
| InₓGa₁₋ₓN | 760° C. | x = 0.05 | 6 |
| (Last barrier (44)) | | | |
| Al_{y}Ga_{1-x-y}InₓN | 820° C. | X = 0.1, | 20 |
| (Electron blocking layer (52)) | | y = 0.2 | |
| p-GaN | 900° C. | | 200 |
| (P-side contact region (52)) | | | |

The thickness of the lateral enhancement layers 36, 37 should be sufficient to cover the rough surface S, with no upper limit. However, if they become too thick (e.g., 500 nm), the thick GaN layer will be positioned before the active layer 42, which may significantly degrade the functionality of the superlattice regions 33, 34.

Unlike in the previous examples, the composition of In, Al, and Ga used here were based on predicted values in the solid state after the growth was completed. It should be noted that even with the same composition InxGa1-xN (x=0.1), the actual In content may increase as the growth progresses, and more In may need to be incorporated as the thickness of InGaN increases and as the growth progresses.

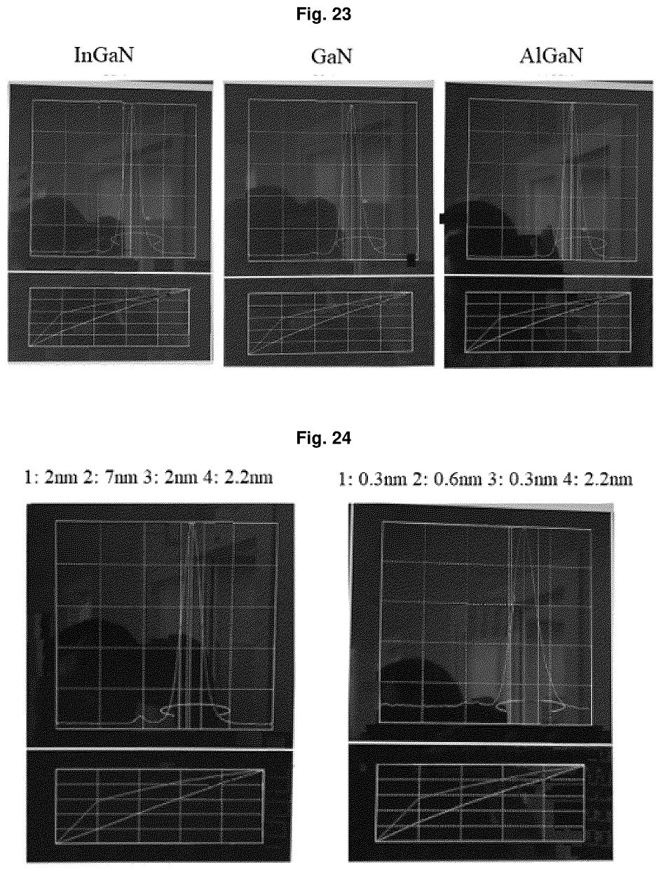

The last barrier 44 was tested with Al_{y}Ga_{1-y}N 44 (y=0.05), GaN 44, and InₓGa₁₋ₓN 44 (x=0.05), and Al_{y}Ga_{1-y}N 44 (y=0.05) showed the best light output. In conventional LED devices, adding Al to the last barrier (44) results in a shift toward shorter wavelengths, while adding In results in a shift toward longer wavelengths. In the device presented in this example, however, adding Al resulted in a shift toward longer wavelengths, and adding In resulted in a shift toward shorter wavelengths. It was found that adjusting the Al and In content enables to achieve a desired red light wavelength. Here, behavior opposite to conventional understanding has been applied, which is presumed to be attributed to strain effects. In the active region 42 presented in Table 8, it turned out that the last In_{0.05}Ga_{0.95}N (0.4 nm)-Al_{0.1}Ga_{0.9}N (0.8 nm)-In_{0.05}Ga_{0.95}N (0.4 nm) in the three cycles can be omitted and Al_{0.05}Ga_{0.95}N (last barrier 44 (6 nm), GaN (last barrier 44 (6 nm), or InₓGa₁₋ₓN (last barrier 44 (6 nm) can be formed instead. In particular, the last barrier 44 mainly comprised of Al_{0.05}Ga_{0.95}N (6 nm) was more effective than the last barrier 44 comprised of In_{0.05}Ga_{0.95}N (0.4 nm)-Al_{0.1}Ga_{0.9}N (0.8 nm)-In_{0.05}Ga_{0.95}N (0.4 nm)-Al_{0.05}Ga_{0.95}N (6 nm). Further, the last barrier 44 comprised of In_{0.05}Ga_{0.95}N (0.4 nm)-Al_{0.1}Ga_{0.9}N (0.8 nm)-In_{0.05}Ga_{0.95}N (0.4 nm)-In_{0.05}Ga_{0.95}N (6 nm) was more effective than the last barrier 44 mainly comprised of In_{0.05}Ga_{0.95}N (6 nm). In addition, the last barrier 44 using In_{0.05}Ga_{0.95}N (6 nm) was more effective than using GaN (6 nm) (see FIG. 23).

The thickness (2.2 nm) of InₓGa₁₋ₓN (active region 42 (x=0.35), which is the region corresponding to the well layer In the active region 42 (in the example shown, the active region 42 has a superlattice structure and forms a miniband, but for convenience of description, the expressions ‘well layer’ and ‘barrier layer’ used in the quantum well structure will be used as they are.) is greater than the thickness (1.6 nm=0.4 nm+0.8 nm+0.4 nm) of InₓGa₁₋ₓN (active region 42 (x=0.05)-Al_{y}Ga_{1-y}N (active region 42 (y=0.1)-InₓGa₁₋ₓN (active region 42 (x=0.05), which is the region corresponding to the barrier layer. It was also confirmed that, in the active region 42, the thinner the barrier layer, the thicker the well layer and the more the wavelength shifts toward longer wavelengths (see FIG. 24).

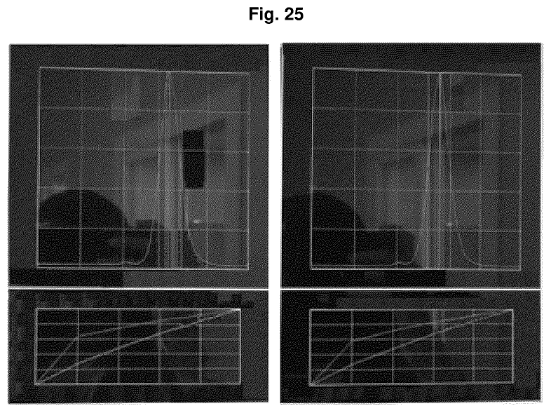

Additionally, as shown, the efficiency was increased by using InGaN—AlGaN—InGaN, instead of a single GaN, as a barrier (layer) (see FIG. 25).

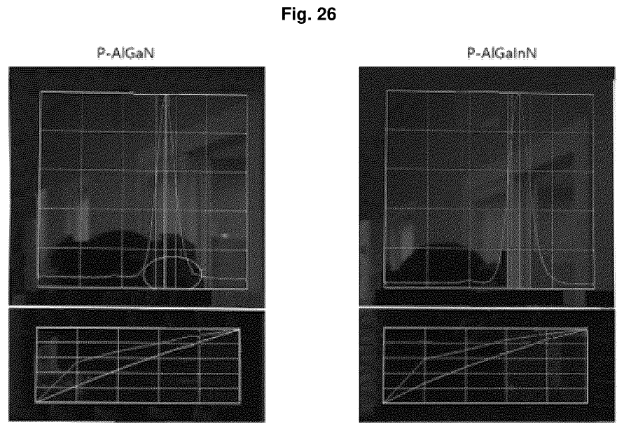

Following the growth of the last barrier 44, the electron blocking layer 51 was grown with AllnGaN, instead of AlGaN, which resulted in a 10% increase in efficiency while shifting toward longer wavelengths (see FIG. 26).

FIG. 22 shows another example of a semiconductor light emitting structure according to the disclosure, which differs from the semiconductor light emitting device shown in FIG. 18 in that the superlattice regions 33, 34 are replaced with strain control regions 38, 39. In general, a superlattice structure is comprised of two or more layers with different band gaps grown alternately, each having a thickness of a few nanometers, forming a miniband due to tunneling.

Table 9 below summarizes examples of growth conditions for the semiconductor light emitting structure of FIG. 22.

TABLE 9

| | Growth | | | |
|---|---|---|---|---|
| | temperature | | Composition | Thickness |
| GaN | 870° | C. | | 1.5 nm |
| (Superlattice region (38)) | | | | |
| InₓGa₁₋ₓN | 770° | C. | x = 0.05 | 30 nm |
| (Superlattice region (38)) | | | | |
| Al_{y}Ga_{1-y}N | 870° | C. | y = 0.2 | 5 nm |
| (Superlattice region (38)) | | | | |
| . | . | | . | . |
| . | . | | . | . |
| . | . | | . | . |
| <<10 cycles>> | | | | |
| . | . | | . | . |
| . | . | | . | . |
| . | . | | . | . |
| GaN | 1000° | C. | | 45 |
| (Lateral enhancement layer | | | | |
| (36)) | | | | |
| GaN | 870° | C. | | 15 |
| (Superlattice region (39)) | | | | |
| InₓGa₁₋ₓN | 770° | C. | x = 0.05 | 30 |
| (Superlattice region (39)) | | | | |
| Al_{y}Ga_{1-y}N | 870° | C. | y = 0.2 | 5 |
| (Superlattice region (39)) | | | | |
| . | . | | . | . |
| . | . | | . | . |
| . | . | | . | . |
| <<10 cycles>> | | | | |
| . | . | | . | . |
| . | . | | . | . |
| . | . | | . | . |
| GaN | 1000° | C. | | 45 |
| (Lateral enhancement layer | | | | |
| (37)) | | | | |
| Al_{y}Ga_{1-y}N | 780° | C. | y = 0.5 | 0.5 |
| (Superlattice region (35)) | | | | |
| InₓGa₁₋ₓN | 730° | C. | x = 0.1 | 1.5 |
| (Superlattice region (35)) | | | | |
| GaN | 830° | C. | | 1.5 |
| (Superlattice region (35)) | | | | |
| . | . | | . | . |
| . | . | | . | . |
| . | . | | . | . |
| <<10 cycles>> | | | | |
| . | . | | . | . |
| . | . | | . | . |
| . | . | | . | . |
| InₓGa₁₋ₓN | 710° | C. | x = 0.35 | 2.2 |
| (Active region (42)) | | | | |
| InₓGa₁₋ₓN | 760° | C. | x = 0.05 | 0.4 |
| (Active region (42)) | | | | |
| Al_{y}Ga_{1-y}N | 760° | C. | y = 0.1 | 0.8 |
| (Active region (42)) | | | | |
| InₓGa₁₋ₓN | 760° | C. | x = 0.05 | 0.4 |
| (Active region (42)) | | | | |
| . | | | | |
| . | | | | |
| . | | | | |
| <<3 cycles>> | | | | |
| . | | | | |
| . | | | | |
| . | | | | |
| Al_{y}Ga_{1-y}N | 760° | C. | y = 0.05 | 6 |
| (Last barrier (44)) | | | | |
| GaN | 760° | C. | | 6 |
| (Last barrier (44)) | | | | |
| InₓGa₁₋ₓN | 760° | C. | x = 0.05 | 6 |
| (Last barrier (44)) | | | | |
| Al_{y}Ga_{1-x-y}InₓN | 820° | C. | X = 0.1, | 20 |
| Electron blocking layer (52)) | | | y = 0.2 | |
| p-GaN | 900° | C. | | 200 |
| P-side contact region (52)) | | | | |

To emit red light, a relatively high In content is required in the active region 42. However, it can be challenging to overcome crystal defects caused by a sharp lattice constant difference between the n-type semiconductor region 30 and the active region 42 with only the superlattice region. These issues can be resolved by introducing one or more strain control regions 38, 39, these issues can be resolved.

The strain control region 38,39 was grown in a hydrogen atmosphere, while the superlattice region 35 and the regions thereafter were grown in a nitrogen atmosphere. Growing in the hydrogen atmosphere improves the growth rate of the strain control region 38,39.

In the strain control regions 38, 39, the thickness of InₓGa₁₋ₓN is set to several tens of nm (e.g., 30 nm), with x in the composition being 0<x<0.3. The thickness of the GaN layer can be set to 10-200 nm, and the thickness of Al_{y}Ga_{1-y}N layer can be set to 1-20 nm, with y in the composition being 0.01<y<0.9. The difference in growth temperature (Δ T) between InₓGa₁₋ₓN and GaN is preferably at least 20 degrees. In other words, the growth temperature of GaN is set higher than that of InₓGa₁₋ₓN.

Compared to the examples presented in Table 8, the thickness of the lateral enhancement layer 36 has been reduced from 100 nm to 45 nm. When the roughness of the surface S is less than the examples in Table 8, the lateral enhancement layer 36 can be formed with a thickness of 50 nm or less.

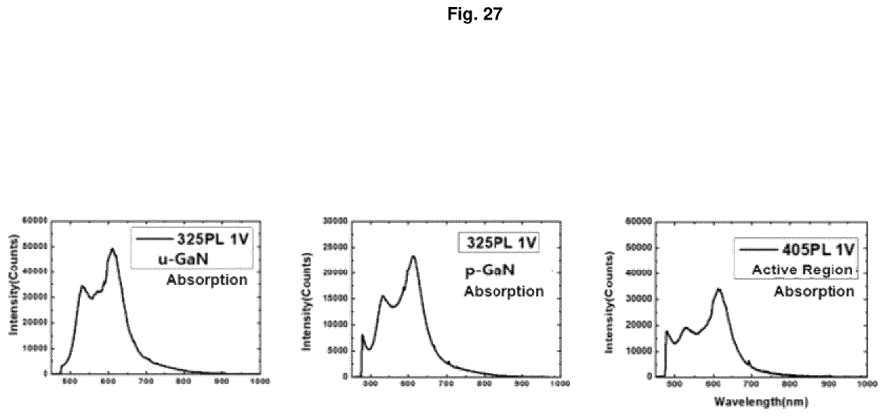

FIG. 27 shows an example of photoluminescence (PL) experiment results in the disclosure, which shows, from left to right, the absorption results of u-GaN with excitation light of a wavelength of 325 nm, the absorption results of p-GaN with excitation light of a wavelength of 325 nm, and the absorption results of the active layer with excitation light of a wavelength of 405 nm. In all cases, only very weak and identical deep level emission was measured. Even when light was selectively absorbed in u-GaN, p-GaN, and the active layer, the same very weak emission spectrum was observed. There was no peak shift due to bias application (since the bias is applied only to the active layer, indicating that it is not active emission). IN the case of 405 nm excitation, only a slight decrease in intensity was observed with reverse bias application (indicating the presence of the same deep level throughout the sample, including the active region).

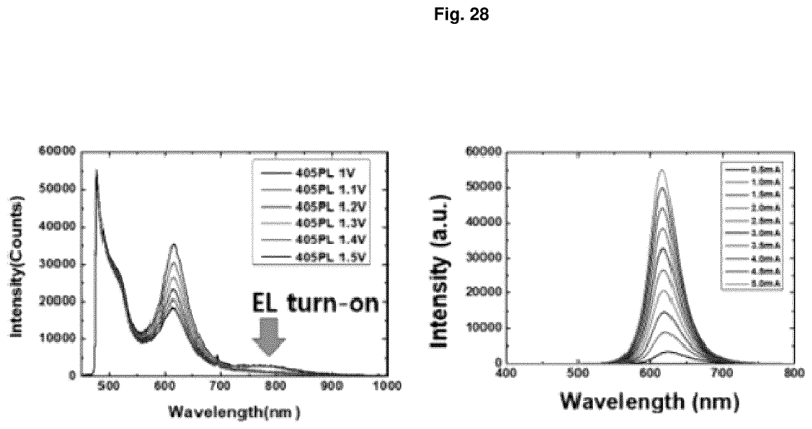

FIG. 28 shows an example of field luminescence (EL) experiment results in the disclosure. The EL resulting from current injection starts at much longer wavelengths compared to photoluminescence (PL) and exhibits an intensity that is several tens of times greater than that of PL at longer wavelengths. Additionally, photoluminescence corresponding to EL was not observed even in low-temperature PL or high-excitation PL. The operating voltage of EL is smaller than the minimum operating voltage (hv/e) obtained from the emission wavelength. These results indicate that PL emission and EL emission occur in spatially separate and distinct regions.

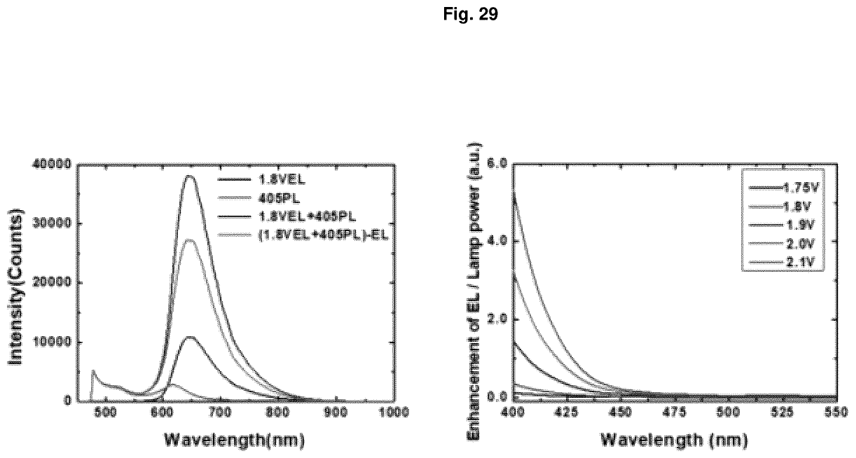

FIG. 29 shows an example of field luminescence (EL) experiment results with a laser being added according to the disclosure. When a laser is added while the EL is on, the intensity of EL increases dramatically (by more than three times). When only the laser is irradiated, very weak, different PL is observed as described above. When excitation light is added to the EL process which occurs by applying a forward voltage, the intensity of EL, of which level depends on the wavelength of the excitation light, increases non-linearly. The laser used here has a wavelength of 405 nm, and its energy is greater than the energy of the well layer but less than the energy of the barrier layer or the p-GaN and n-GaN layers. That is to say, the laser is selectively absorbed only in the well layer.

To summarize the experiment results from FIGS. 27 to 29, (i) EL is observed, but PL is not; (ii) Absorption by the excitation laser during PL occurs in the quantum well layer (this is experimentally confirmed from photocurrent measurements); (iii) In PL, laser absorption occurs in the quantum well layer, but the emission from the quantum well layer is not observed; (iv) The quantum well layer has a high density of non-radiative recombination centers, leading to very low photoluminescence efficiency; and (v) EL and PL occur in different regions that are spatially separated from each other.

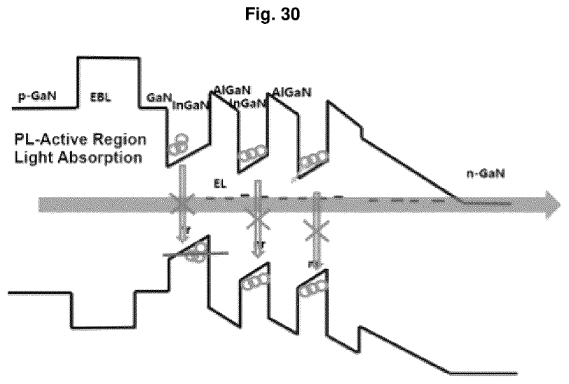

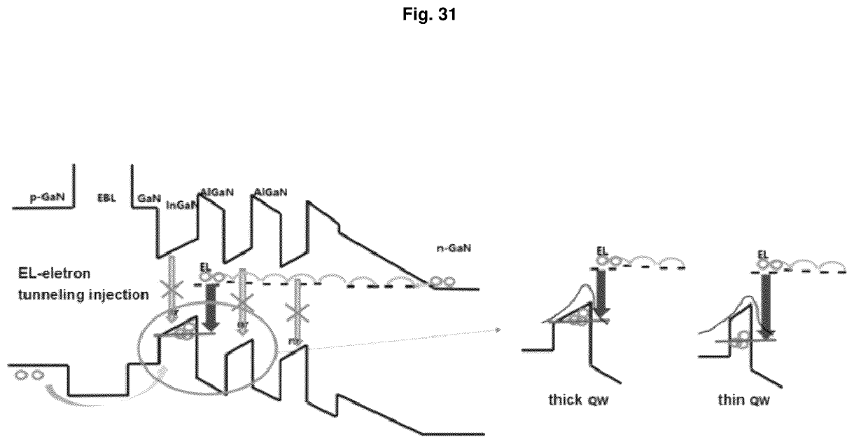

FIG. 30 schematically illustrates the emission mechanism that is consistent with these findings, that is, luminescence through tunneling injection (Paper: Tunnel Injection and Power Efficiency of InGaN/GaN Light emitting Diodes; ISSN 1063-7826, Semiconductors, 2013, Vol. 47, No. 1, pp. 127-134. @Pleiades Publishing, Ltd., 2013). Electrons are injected by tunneling into a low-energy state in the AlGaN barrier layer. It is believed that in EL, electron-hole recombination occurs by avoiding the quantum well layer with a high density of non-radiative recombination centers. In addition, the barrier has a low density of non-radiative recombination centers, so that high-efficiency, low-energy (longer wavelength) light emission is possible. Further, EL can be observed with a low operating voltage (see FIG. 31).

It would be worthy of noting what enables emission through tunneling injection in the semiconductor light emitting device according to the disclosure, which differs from the conventional GaN-based LEDs. As shown in FIG. 21, when a lateral enhancement layer 36 or 37 is not introduced between the active region 42 and its nearest superlattice region 35, such emission occurs. However, this is not the case when the lateral enhancement layer 36 or 37 is introduced. Therefore, aside from the understanding that the active region 42 grown on the semi-polar plane can increase indium injection when the lateral enhancement layer 36 or 37 is not present, tunneling injection becomes possible by growing the active region 42 without recovering the defects created by the rough surface S through the lateral enhancement layer 36 or 37.

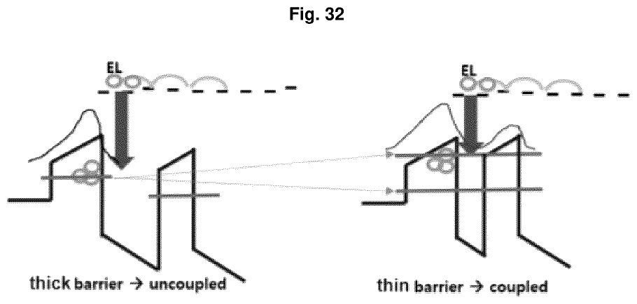

As shown in FIG. 32, as the barrier thickness decreases, coupling occurs between the last quantum well (QW) and the second-to-last QW. This splits the energy state of the QW into two, with the ground state energy becoming lower (the wavelength becomes longer) (Paper: Effect of electric fields on excitons in a coupled double-quantum-well structure; PHYSICAL REVIEW B VOLUME 36, NUMBER 8 15 Sep. 1987-I). This finding is consistent with the experiment results shown in FIG. 24, which states that ‘as the barrier layer in the active region 42 and the well layer get thicker, the wavelength gets longer’. Therefore, according to the experiment results and interpretation of this disclosure, the emission wavelength can be controlled to a longer wavelength by making the last barrier thinner and the last well layer thicker.

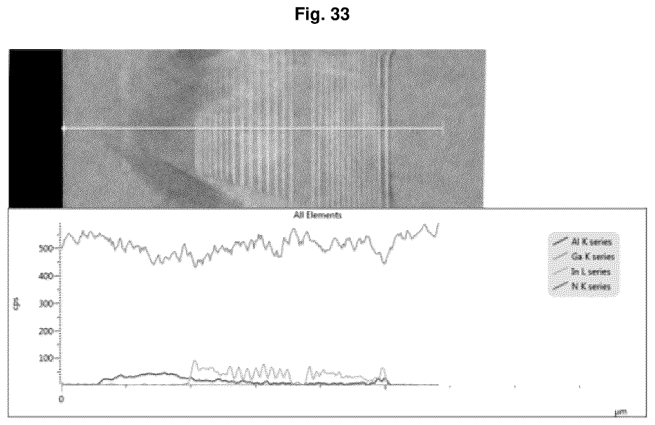

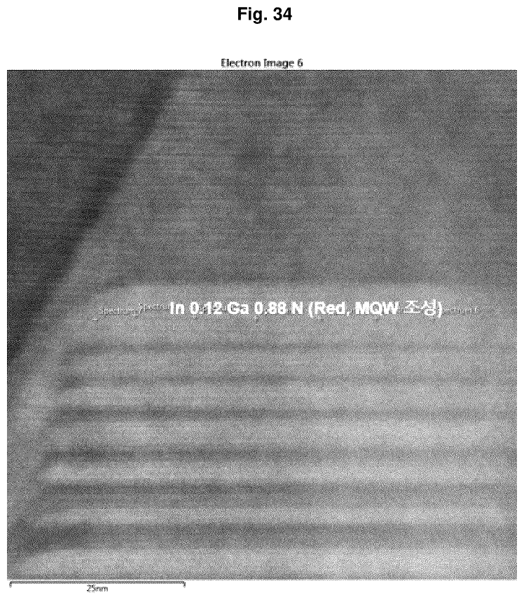

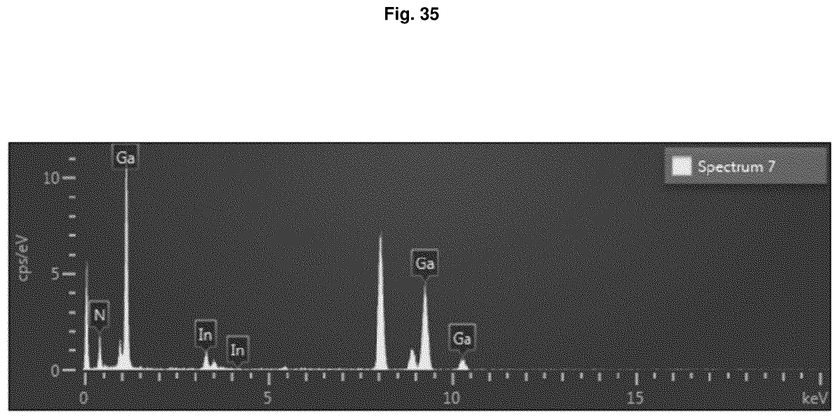

FIGS. 33 to 35 show other examples of measurement results in the disclosure. FIG. 33 presents ESD analysis results, and FIGS. 34 to 35 present point composition analysis results. As a result of measuring 7 points on the last quantum well layer among the 3-cycle quantum well layers of the active area 42 presented in FIG. 22, the contents (x) of indium (In) were measured as 12.90%, 11.26%, 10.94%, 11.49%, 12.25%, 10.89%, and 13.42%, respectively. The average value of the contents was approximated to 12% (rounded up from 11.88%), falling in the range of 10 to 20%. From these results, it was confirmed that the quantum well layer of the red-emitting III-nitride semiconductor light emitting device according to the disclosure has an indium content that is typical of quantum wells emitting green or blue light based on the measured value, but it actually emits red light. The theoretical explanation consistent with these results seems to be related to the experiment results described in FIGS. 27 to 29. Therefore, according to these measurement results, the III-nitride semiconductor light emitting device according to the disclosure can be defined as having a quantum well layer of InₓGa₁₋ₓN with an indium content (x) value (as measured) theoretically expected to emit blue light (approximately 0.1) or green light (approximately 0.2) but actually emitting red light. In the example shown, the device should theoretically emit light of 500 nm or less, but it actually emits light of 600 nm or more. A broad interpretation of this is that it is possible to manufacture a III-nitride semiconductor light emitting device that emits light with a wavelength of 600 nm or more from an active region having a quantum well layer with an indium content (x) corresponding to an emission wavelength below 600 nm (further below 500 nm).

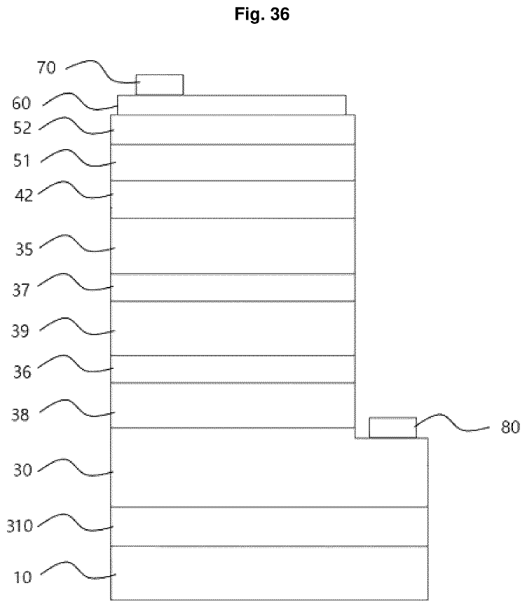

FIG. 36 shows another example of a semiconductor luminescence structure or light emitting device according to the disclosure, which differs from the semiconductor light emitting device shown in FIG. 22 in that the buffer region 20 is replaced with a III-nitride semiconductor layer 310. One example of a method for forming such a III-nitride semiconductor layer 310 is provided in US Patent Application Publication No. 2016-0013275. This configuration improves the overall crystallinity of the device, assists the external emission of light generated in the active region 40, and facilitates the removal of the growth substrate 10 if it is to be removed. The following will include the description of any component that has not been explained.

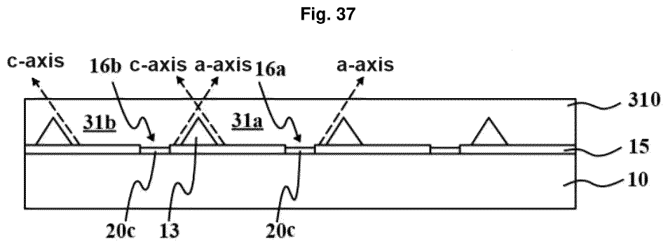

FIG. 37 shows one example of a III-nitride semiconductor stack according to the disclosure, in which the III-nitride semiconductor stack includes an m-plane substrate 10, a growth inhibitor film having a plurality of windows 16a, 16b for growing a III-nitride semiconductor, a seed layer 20c formed at regions corresponding to the plurality of windows 16a, 16b on the m-plane substrate 10 in the region, a III-nitride semiconductor layer 310 grown from the seed layer 20c and coalesced after propagated along a-axis and c-axis directions, in which a III-nitride semiconductor 31a propagated along the c-axis direction from one window 16a and then propagated above the growth inhibitor film 15 forms a cavity 13 with a III-nitride semiconductor 31b propagated along the a-axis direction from a neighboring window 16b.

A typical material for the m-plane substrate 10 is hexagonal sapphire, in which the m-plane is 1-100 and the a-plane is 11-20, with respect to the c-plane 0001. Here, the a-axis is defined as an axis normal to the a-plane, and the c-axis is defined as an axis normal to the c-plane. While it is preferred to use an accurate m-plane substrate 10, any substrate that is cut at a slight angle from the m-plane may also be used. These substrates are collectively called the m-plate substrate 10 in the description. Besides sapphire, any material that is capable of supporting the growth of III-nitride semiconductors (e.g., GaN, InGaN, AlGaN, InN, AlN, InGaAlN) and has an m-plane may be used. The III-nitride semiconductor can be doped with a material such as Si or Mg.

The growth inhibitor film 15 is usually made of SiO₂. It can also be made of SiNₓ or TiO₂ or any material that prevents the growth of III-nitride semiconductors. In addition, the growth inhibitor film 15 can be formed into a SiO₂/TiO₂ DBR structure. For instance, a SiO₂ film having a thickness of 100 to 300 nm can be used. Moreover, the growth inhibitor film 15 can be formed into stripes along the a-plane direction of the m-plane sapphire substrate, and a gap between the growth inhibitor film 15 and the window 16a can be suitably adjusted. The inventors have conducted experiments on masks (unit: μm) with various gaps of 17:1, 16:2, 13:1, 14:2, 7:3, 6:2 between the growth inhibitor film 15 and the window 16a and found that the III-nitride semiconductor layer 31 (GaN) could be planarized to 7 μm or less (i.e. the height of the cavity 13 becomes 7 μm or less) even when the growth inhibitor film 15 has a maximum width of 17 μm. Therefore, according to the method for growing a III-nitride semiconductor according to the disclosure, it is possible to planarize the III-nitride semiconductor layer 310 before reaching an excessive height (e.g., 10 μm).

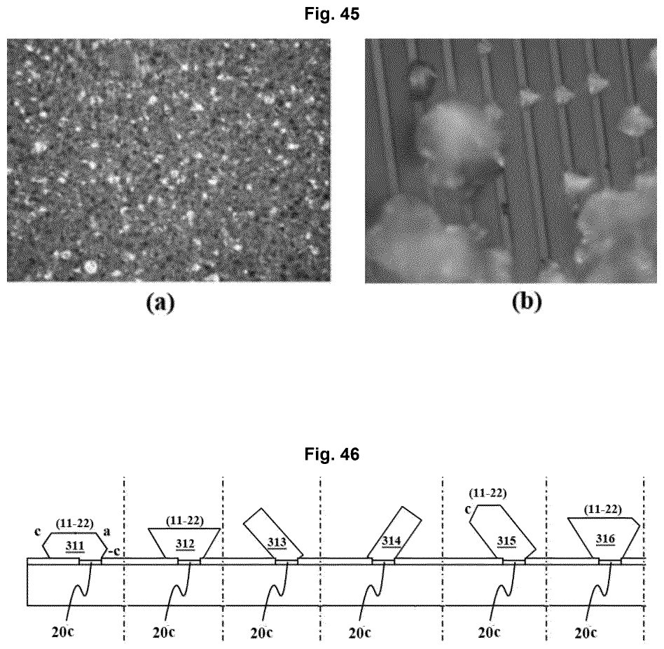

Unlike a GaN buffer layer that is typically formed at approximately 500° C. (e.g., 550° C.), the seed layer 20c (e.g., GaN) is formed at a high temperature not lower than 650° C., preferably not lower than 800° C., yet it is not formed properly at a temperature of 1150° C. or higher. Although it is possible to form a superior seed layer 20c at a temperature of 800° C. or higher, the seed layer can grow at a temperature of 900° C. or higher, for quick shifting to the growth conditions for the III-nitride semiconductor layer 310 growing at a higher temperature. From this point of view, the seed layer is preferably grown at a temperature not lower than 900° C. Moreover, N₂ is used as a carrier gas in place of conventionally used H₂. As indicated above, the use of a conventional buffer layer results in the formation of polycrystals over the growth inhibitor film 15, making it difficult to obtain a III-nitride semiconductor layer 310 having excellent crystallinity. As such, it will be understood that the seed layer 20c according to this embodiment is different from a conventional buffer layer used for growing III-nitride semiconductor layers, in terms of its formation. FIG. 45 shows photos of a seed layer grown at a low temperature, and under hydrogen atmosphere, respectively. As can be seen in (a), when a seed layer is grown at a low temperature, polycrystals cover up to the growth inhibitor film. As can be seen in (b), when a seed layer is grown under hydrogen atmosphere, the seed layer might not grow well, and rather very large nuclei may be formed in some parts. FIG. 46 shows a photo of a seed layer grown according to the disclosure. As can be seen in the figure, a seed layer 20c is formed at the window 16a only. Since the seed layer 20c grows in a narrow window 16a region, those growth conditions free of a growth inhibitor film 15 may cause the seed layer 20c to form at the window 16a too quickly such that it is necessary to modify the growth rate based on the size of the window 16a. The seed layer 20c is composed of a compound semiconductor Al(x)Ga(y)In(1-x-y)N (0=x=1, 0=y=1, 0=x+y=1), preferably GaN. The seed layer 20c in FIG. 46 is grown in following growth conditions. An m-plane sapphire undergoes organic cleansing, SiO₂ is deposited by PECVD thereon, and then a seed layer is grown by MOCVD. For an MOCVD reactor, N₂ is employed as an atmosphere gas, and NH₃ is introduced into the reactor at a designated flow rate of 8000 sccm (Standard Cubic Cm per Min.), starting from 450° C. up to 1050° C. This is done for nitriding treatment of the sapphire surface. At 1050° C., GaN nuclei were grown at a rate of 0.5 nm/sec using TMGa. Here, the pressure in the reactor was set to 100 mbar.

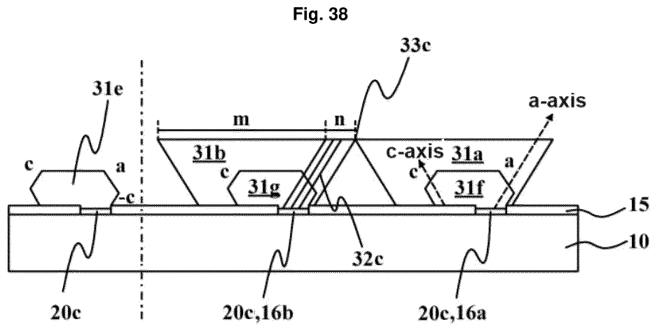

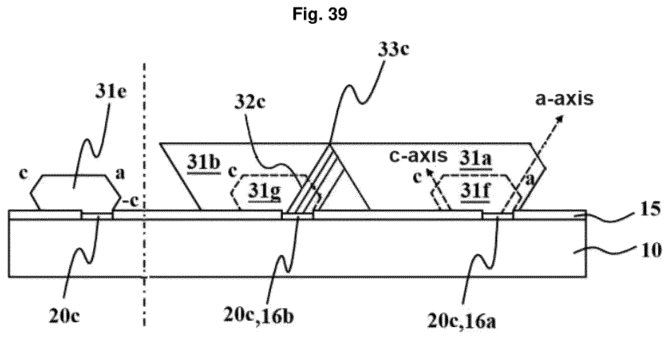

FIG. 38 shows an example of a method for growing III-nitride semiconductors on a seed layer according to the disclosure. In particular, an example of the process for coalescing a III-nitride semiconductor 31a and a III-nitride semiconductor 31b is described. As can be seen from the left side of FIG. 38, a III-nitride semiconductor 31e on a seed layer 20c of an m-plate substrate 10 can be grown with a c-plane, an a-plane and a −c-plane in the clockwise direction. Given that the lateral propagation along the a-axis direction is basically suppressed relative to the lateral propagation along the c-axis direction, a certain plane may be created broader, or a certain plane may be omitted, depending on the growth conditions. In addition, as can be seen from the photo in the middle of FIG. 38, crystal defects 32c (more precisely, stacking faults) are propagated along the a-axis direction. Therefore, a region n having crystal defects is made relatively narrower than a region m without crystal defects 32c when the III-nitride semiconductor 31a grown at the window 16a and the III-nitride semiconductor 31b grown at the neighboring window 16b reach a coalescence point 33c, the region n is formed as it is propagated or grown along the a-axis direction and the region m is formed as it is propagated or grown along the c-axis direction, such that crystal defects across the III-nitride semiconductors 31a, 31b may be reduced. For proper coalescence, the a-planes of the III-nitride semiconductors 31a, 31b propagated along the a-axis direction are gradually reduced, optimally creating a point coalescence. Also, coalescence or planarization of the IIII-nitride semiconductor 31b propagated along the a-axis direction and the III-nitride semiconductor 31a propagated along the c-axis direction is assisted by reducing the c-plane of the III-nitride semiconductor 31a propagated along the c-axis direction, optimally creating a point coalescence or junction, up to the coalescence point 33c. When the −c-plane of the III-nitride semiconductor 31b and the c-plane of the III-nitride semiconductor 31a meet at the coalescence point 33c, they may not be coalesced easily, or they may grow in parallel without being coalesced. Preferably, those III-nitride semiconductors 31a, 31b grow after sub III-nitride semiconductor bulks 31f, 31g grown and propagated over a growth inhibitor region as the lateral growth-propagation rate of the III-nitride semiconductor propagated or grown along the c-axis direction is faster than that of the III-nitride semiconductor propagated along the a-axis direction, and/or sub III-nitride semiconductor bulks 31f, 31g having both a-plane and c-plane still existent are formed first. Because the height of an III-nitride semiconductor can be increased towards the coalescence point 33c in case of forming a III-nitride semiconductor of reversed trapezoidal shape from the early stage of the growth process, it is desirable to make the sub III-nitride semiconductor bulks 31f, 31g propagated over the growth inhibitor film 15 in advance. Moreover, since it is not necessarily easy to incorporate the III-nitride semiconductors 31a, 31b in reversed trapezoidal shape, it is desirable to prepare the sub III-nitride semiconductor bulks 31f, 31g in advance, as preforms for making such a shape. As described above, according to the method for growing a III-nitride semiconductor of the disclosure, the III-nitride semiconductor layer 310 can still be coalesced at a thickness of 7 μm or less even when the ratio of widths of the growth inhibitor film 15 to the window 16a is 17:1, in which the sub III-nitride semiconductor bulks 31f, 31g are one of useful means for accomplishing it. After the seed layer 20c is grown, the atmosphere gas is changed to hydrogen. Then the sub III-nitride semiconductor bulks 31f, 31g are grown to a thickness range between 500 and 1300 nm, under 4000 sccm of NH₃, at the pressure of 100 mbar, the temperature of 1050° C., and the growth rate of 0.6 nm/sec. The growth process is continued, after lowering the temperature to 920° C. and setting the pressure to 250 mbar and NH₃ to 12,000 sccm. For instance, a structure as shown in FIG. 38 can be obtained by growing the sub III-nitride semiconductor bulks 31f, 31g to a thickness of 500 nm, and the region n can be reduced merely to 5% of the whole surface, thereby significantly reducing crystal defects 32c. In addition, a structure as shown in FIG. 39 can be obtained by growing the sub III-nitride semiconductor bulks 31f, 31g to a thickness of 1300 nm, and crystal defects 32c may be blocked such that they would not break through the surface. Comparing the growth conditions of two layers, once the sub III-nitride semiconductor bulks 31f, 31g are grown at a relatively low pressure and a relatively high temperature, the III-nitride semiconductors 31a, 31b grown after the sub III-nitride semiconductor bulks 31f, 31g become relatively less sensitive to temperatures in their growth.

FIG. 39 shows another example of a method for growing III-nitride semiconductors on a seed layer according to the disclosure. In particular, another example of the coalescence process for a III-nitride semiconductor 31a and a III-nitride semiconductor 31b is described. Crystal defects 32c of the III-nitride semiconductor 31b propagated along the a-axis direction are blocked by the III-nitride semiconductor 31a. Likewise, by reducing the c-plane of the III-nitride semiconductor 31a that propagates along the c-axis direction up to a coalescence point 33c where the junction is completed, optimally a point coalescence is created. This aids in the coalescence or planarization of the III-nitride semiconductor 31b propagated along the a-axis direction and of the III-nitride semiconductor 31a propagated along the c-axis direction and prevents the propagation of crystal defects 32c.

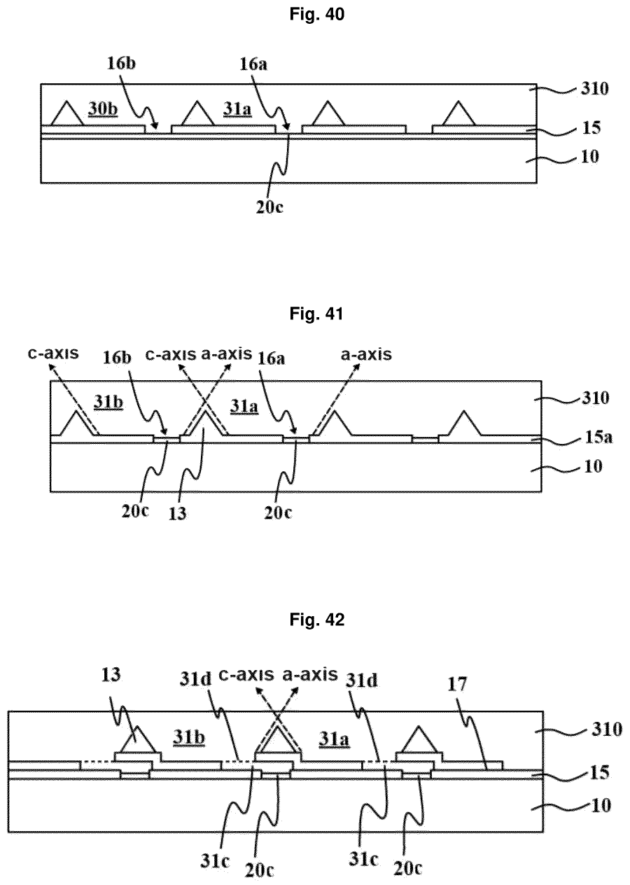

FIG. 40 shows another example of a III-nitride semiconductor stack according to the disclosure, which has a seed layer 20c disposed between a growth inhibitor film 15 and an m-plane substrate 10, as compared with the III-nitride semiconductor stack of FIG. 37. That is, the seed layer 20c is formed prior to the formation of the growth inhibitor film 15. Those problems noted in connection with FIG. 4 may occur if a semiconductor layer is formed first, but they can be resolved by limiting the height of the seed layer 20c. In case of this embodiment, the seed layer 20c may be formed of a conventional buffer layer

FIG. 41 shows another example of a III-nitride semiconductor stack according to the disclosure, in which the III-nitride semiconductor 310 is grown after a growth inhibitor film 15 is removed, as compared with the III-nitride semiconductor stack of FIG. 37. As such, a region 15a in an m-plane substrate 10 where a seed layer 20c is not formed serves as a growth inhibitor region. As the region 15a is free of the seed layer 20c, the III-nitride semiconductor layer 310 does not grow therein. As a result, the III-nitride semiconductor layer 310 grows from the seed layer 20c, as in FIG. 37. In other words, the III-nitride semiconductor 31a propagated along the c-axis direction from the window 16a forms a cavity 13 with the III-nitride semiconductor 31b propagated along the a-axis direction from the neighboring window 16b by growing over the region 15a. Since the growth inhibitor film 15 is removed prior to the growth of the III-nitride semiconductor layer 310, the III-nitride semiconductor layer 310 can grow without facing any problem even when polycrystals are produced during the formation of the seed layer 20c on the growth inhibitor film 15.

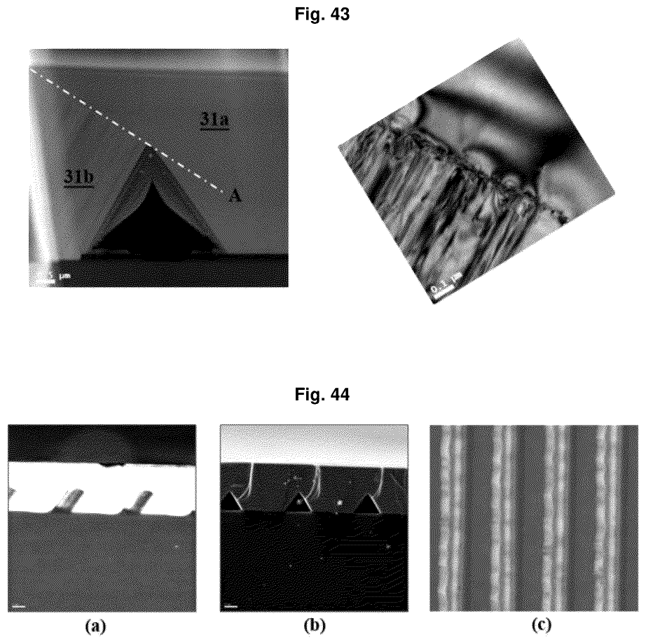

FIG. 42 shows another example of a III-nitride semiconductor stack according to the disclosure, in which the III-nitride semiconductor stack includes an additional growth inhibitor film 17 having a cavity 13 thereon. The cavity 13 is formed by interrupting the growth of a III-nitride semiconductor 31c on a seed layer 20c, forming an additional growth inhibitor film 17 such that a plane 31d of the III-nitride semiconductor 31c propagated along the c-axis direction again is exposed, and then growing a III-nitride semiconductor 31a and a III-nitride semiconductor 31b from the plane 31d, 31d. As mentioned above, and will be described below, the region where the III-nitride semiconductor 31c is propagated along the c-axis direction on the growth inhibitor film 15 is nearly free of defects (see FIG. 43) such that a III-nitride semiconductor layer 310 formed thereon can have substantially reduced crystal defects.

FIG. 43 shows sectional images of the III-nitride semiconductor stack of FIG. 39, which has grown in the structure illustrated in FIG. 39, in which the image on the right-hand side is a STEM (Scanning Transmission Electronic Microscope) image, and the image on the left-hand side is a TEM (Transmission Electronic Microscope) image. As can be seen from the STEM image, with respect to a coalescence plane A, those defects propagated from a III-nitride semiconductor 31b are blocked by a III-nitride semiconductor 31a, while the III-nitride semiconductor 31a, i.e., a III-nitride semiconductor propagated or grown along the c-axis direction, is nearly free of crystal defects. These features can be utilized advantageously in the growth of the III-nitride semiconductor stack shown in FIG. 42. Blocking of defects can be seen more clearly from the TEM image.

FIG. 44 shows sectional images of the III-nitride semiconductor stack of FIG. 37, which has grown in the structure illustrated in FIG. 39, in which (a) is a CL (Cathodoluminescence) image, (b) is an SEM (Scanning Electron Microscope) image, and (c) is an optical microscope image. In the CL image, defects correspond to trenches formed in an obliquely upward right direction, which are kept from being propagated any further. The SEM image shows a cavity which is formed across the substrate. One thing that looks like a defect on the upper right side of the cavity is a flaw produced while cross cutting. In the optical microscope image, a brighter side corresponds to a cavity, and a clear surface thereof makes it possible to see inside the III-nitride semiconductor layer.

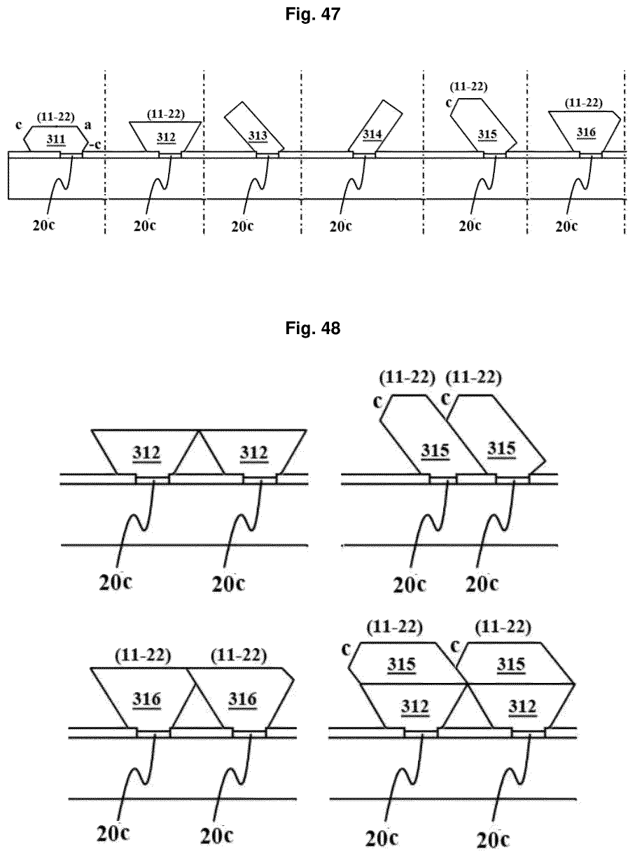

FIGS. 47 to 48 show an example of a method for growing a III-nitride semiconductor according to the disclosure. In reference to a III-nitride semiconductor 311, a III-nitride semiconductor 312 can grow along the a- and c-plane directions at similar growth rates, given that these growth rates are relatively faster than the growth rates along the 11-22 plane directions. A III-nitride semiconductor 313 can grow at varied growth rates that are modified in the order of 11-22 plane direction>c-plane direction>a-plane direction. A III-nitride semiconductor 314 can grow at varied growth rates that are modified in the order of 11-22 plane direction>a-plane direction>c-plane direction. A III-nitride semiconductor 315 can grow at varied growth rates that are modified in the order of c-plane direction>11-22 plane direction>a-plane direction, given that the growth rate along the c-plane direction being slightly faster than the growth rate along the 11-22 plane direction. A III-nitride semiconductor 316 can grow at varied growth rates that are modified in the order of c-plane direction>a-plane direction>11-22 plane direction, given that the growth rate along the c-plane direction being slightly faster than the growth rate along the a-plane direction. FIG. 48 illustrates a coalescence process of easily planarizable III-nitride semiconductors, i.e. a III-nitride semiconductor 312, a III-nitride semiconductor 315 and a III-nitride semiconductor 316, each having a 11-22 plane. The III-nitride semiconductor 315 retains a c-plane even after the coalescence process. Accordingly, the III-nitride semiconductor 312 and the III-nitride semiconductor 316 can be planarized to a low height. Moreover, it is possible to block a region n by forming the III-nitride semiconductor 312 before growing the III-nitride semiconductor 315, namely, by making the region n illustrated in FIG. 38 narrower than the region m and then blocking the region n.

Various exemplary embodiments of the present disclosure are described below.

(1) A III-nitride semiconductor light emitting device comprising: a first semiconductor region having a first conductivity; a second semiconductor region having a second conductivity different from the first conductivity; and an active region which is interposed between the first semiconductor region and the second semiconductor region, has an InₓGa₁₋ₓN (0.1≤x≤0.2) region that generates light, and emits red light with an emission peak wavelength of 600 nm or more.

(2) The III-nitride semiconductor light emitting device of embodiment (1), further comprising a III-nitride semiconductor layer having a cavity under the first semiconductor region.

(3) The III-nitride semiconductor light emitting device of embodiment (2), further comprising an m-plane growth substrate under the III-nitride semiconductor layer.

(4) The III-nitride semiconductor light emitting device of embodiment (1), wherein the active region is grown on a rough surface formed of semi-polar planes.

(5) A III-nitride semiconductor light emitting device comprising: an active region that emits red light; a semi-polar plane for growing the active region that is disposed below the active region; and an m-plane growth substrate on which the active region and the semi-polar plane are grown.

(6) The III-nitride semiconductor light emitting device of embodiment (5), wherein the active region is grown on a rough surface composed of semi-polar planes.

(7) The III-nitride semiconductor light emitting device of embodiment (6), comprising: a superlattice region with a rough surface.

(8) The III-nitride semiconductor light emitting device of embodiment (7), wherein the superlattice region has an AlGaN—InGaN interface.

(9). A III-nitride semiconductor light emitting device comprising: a first semiconductor region having a first conductivity; a second semiconductor region having a second conductivity different from the first conductivity; and an active region which is interposed between the first semiconductor region and the second semiconductor region and emits red light through tunneling injection.

(10) The III-nitride semiconductor light emitting device of embodiment (9), further comprising a III-nitride semiconductor layer with a cavity for light scattering under the first semiconductor region.

(11) A III-nitride semiconductor light emitting device comprising: a first semiconductor region having a first conductivity; a second semiconductor region having a second conductivity different from the first conductivity; an active region which is interposed between the first semiconductor region and the second semiconductor region, has an InₓGa₁₋ₓN (0.1≤x≤0.2) region that generates light, and emits red light with an emission peak wavelength of 600 nm or more; a III-nitride semiconductor layer having a cavity under the first semiconductor region; and a growth substrate under the III-nitride semiconductor layer.

(12) A method for emitting red light using a III-nitride semiconductor light emitting device, the method comprising: manufacturing a III-nitride semiconductor light emitting device comprising: a first semiconductor region having a first conductivity; a second semiconductor region having a second conductivity different from the first conductivity; an active region which is interposed between the first semiconductor region and the second semiconductor region, has an InₓGa₁₋ₓN (0.1≤x≤0.2) region that generates light, and emits red light with an emission peak wavelength of 600 nm or more; a III-nitride semiconductor layer having a cavity under the first semiconductor region; and an m-plane growth substrate under the III-nitride semiconductor layer; and emitting red light from the active region by passing current through the first and second semiconductor regions.

(13) The method for emitting red light using a III-nitride semiconductor light emitting device of embodiment (12), wherein the active region is grown on a rough surface composed of semi-polar planes.

(14) The method for emitting red light using a III-nitride semiconductor light emitting device of embodiment (12), wherein the active region emits red light by tunneling injection.

(15) A method for emitting red light using a III-nitride semiconductor light emitting device, the method comprising: manufacturing a III-nitride semiconductor light emitting device comprising: a first semiconductor region having a first conductivity; a second semiconductor region having a second conductivity different from the first conductivity; and an active region which is interposed between the first semiconductor region and the second semiconductor region, has an InₓGa₁₋ₓN (0.1≤x≤0.2) region that generates light, and emits red light with an emission peak wavelength of 600 nm or more; and emitting red light from the active region by passing current through the first and second semiconductor regions.

(16) The method for emitting red light using a III-nitride semiconductor light emitting device of embodiment (15), further comprising: growing a superlattice region with a rough surface.

(17) The method for emitting red light using a III-nitride semiconductor light emitting device of embodiment (15), wherein the superlattice region has an AlGaN—InGaN interface.

The III-nitride semiconductor light emitting device and the method for emitting red light using the device according to the disclosure make it possible to practically implement a III-nitride semiconductor light emitting device that emits red light and to practically emit red light using the device.

### DESCRIPTION OF REFERENCE NUMERALS

10: growth substrate, 20: buffer region, 30: n-side contact region, 31: superlattice region, 42: active region, 51: electron blocking layer, 52: p-side contact region 52, 60: current spreading electrode, 70: first electrode, 80: second electrode, 310: III-nitride semiconductor layer

What is claimed is:

1. A III-nitride semiconductor light emitting device comprising:
a first semiconductor region having a first conductivity;
a second semiconductor region having a second conductivity different from the first conductivity; and
an active region which is interposed between the first semiconductor region and the second semiconductor region, has an InₓGa₁₋ₓN (0.1≤x≤0.2) region that generates light, and emits red light with an emission peak wavelength of 600 nm or more.

2. The device of claim 1, further comprising: a III-nitride semiconductor layer having a cavity under the first semiconductor region.

3. The device of claim 2, further comprising: an m-plane growth substrate under the III-nitride semiconductor layer

4. The device of claim 1, wherein the active region is grown on a rough surface formed of semi-polar planes.

5. A III-nitride semiconductor light emitting device comprising:
an active region that emits red light;
a semi-polar plane for growing the active region that is disposed below the active region; and
an m-plane growth substrate on which the active region and the semi-polar surface are grown.

6. The device of claim 5, wherein the active region is grown on a rough surface composed of semi-polar planes.

7. The device of claim 6, comprising:
a superlattice region with a rough surface.

8. The device of claim 7, wherein the superlattice region has an AlGaN—InGaN interface.

9. A III-nitride semiconductor light emitting device comprising:
a first semiconductor region having a first conductivity;
a second semiconductor region having a second conductivity different from the first conductivity; and
an active region which is interposed between the first semiconductor region and the second semiconductor region and emits red light through tunneling injection.

10. The device of claim 9, further comprising:
a III-nitride semiconductor layer with a cavity for light scattering under the first semiconductor region.

11. A III-nitride semiconductor light emitting device comprising:
a first semiconductor region having a first conductivity;
a second semiconductor region having a second conductivity different from the first conductivity;
an active region which is interposed between the first semiconductor region and the second semiconductor region, has an InₓGa₁₋ₓN (0.1≤x≤0.2) region that generates light, and emits red light with an emission peak wavelength of 600 nm or more;
a III-nitride semiconductor layer having a cavity under the first semiconductor region; and
a growth substrate under the III-nitride semiconductor layer.

12. The device of claim 11, further comprising:
a semi-polar plane for growing the active region that is disposed below the active region.

13. The device of claim 11, wherein the active region emits red light through tunneling injection.

14. A method for emitting red light using a III-nitride semiconductor light emitting device, the method comprising:
manufacturing a III-nitride semiconductor light emitting device comprising: a first semiconductor region having a first conductivity; a second semiconductor region having a second conductivity different from the first conductivity; an active region which is interposed between the first semiconductor region and the second semiconductor region, has an InₓGa₁₋ₓN (0.1≤x≤0.2) region that generates light, and emits red light with an emission peak wavelength of 600 nm or more; a III-nitride semiconductor layer having a cavity under the first semiconductor region; and an m-plane growth substrate under the III-nitride semiconductor layer; and
emitting red light from the active region by passing current through the first and second semiconductor regions.

15. The method of claim 14, wherein the active region is grown on a rough surface composed of semi-polar planes.

16. The method of claim 14, wherein the active region emits red light by tunneling injection.

17. A method for emitting red light using a III-nitride semiconductor light emitting device, the method comprising:
manufacturing a III-nitride semiconductor light emitting device comprising: a first semiconductor region having a first conductivity; a second semiconductor region having a second conductivity different from the first conductivity; and an active region which is interposed between the first semiconductor region and the second semiconductor region, has an InₓGa₁₋ₓN (0.1≤x≤0.2) region that generates light, and emits red light with an emission peak wavelength of 600 nm or more; and
emitting red light from the active region by passing current through the first and second semiconductor regions.

18. The method of claim 17, wherein the active region is grown on a rough surface composed of semi-polar planes.

19. The method of claim 18, further comprising:
growing a superlattice region with a rough surface.

20. The method of claim 19, wherein the superlattice region has an AlGaN—InGaN interface.
